(19) United States
(12) Patent Application Publication
(10) Pub. No.: US 2012/0214269 A1
(43) Pub. Date: Aug. 23, 2012

(54) TETRAPHENYLSILANE COMPOUNDS SUITABLE AS ORGANIC HOLE-TRANSPORT MATERIALS

(75) Inventor: Brett T. HARDING, Carlsbad, CA (US)

(73) Assignee: NITTO DENKO CORPORATION, Osaka (JP)

(21) Appl. No.: 13/397,342

(22) Filed: Feb. 15, 2012

Related U.S. Application Data
(60) Provisional application No. 61/443,964, filed on Feb. 17, 2011.

(51) Int. Cl. H01L 51/56; H01B 1/12; C07F 7/10

(52) U.S. Cl. 438/46; 556/413; 548/406; 252/500; 257/E51.026

(57) ABSTRACT

A tetraphenylsilane compound suitable as an organic hole-transport material is represented by a formula:

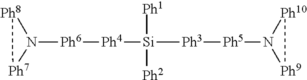

wherein each dashed line indicates an optional bond; and Ph¹, Ph², Ph³, Ph⁴, Ph⁵, Ph⁶, Ph⁷, Ph⁸, Ph⁹, and Ph¹⁰ are independently optionally substituted phenyl or phenylene.

### CROSS-REFERENCE TO RELATED APPLICATIONS

This application claims the benefit of U.S. Provisional Application No. 61/443,964, filed Feb. 17, 2011, the disclosure of which is herein incorporated by reference in its entirety.

### BACKGROUND

1. Field of the Invention

The present invention generally relates to a field of organic chemistry and organic light emitting diode materials. More specifically, the present invention relates to the development of compounds suitable as organic hole-transport materials.

2. Description of the Related Art

Organic light-emitting devices (OLEDs) have been widely developed for flat panel display, and are moving fast towards solid state lighting (SSL) applications. It is generally considered that a white OLED device needs to achieve power efficiency >100 μm/w with color rendering index (CRI)>70 and operating time >10,000 hours @ 1000 cd/cm² to be qualified as a SSL application. In order to reduce the driving voltage of the OLED device and extend the operational lifetime, development of high performance hole-transport materials is necessary.

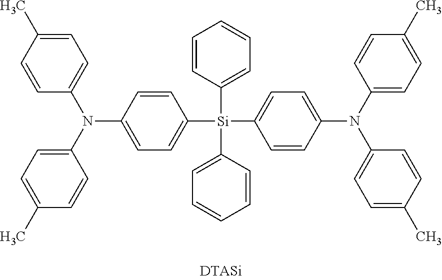

DTASi (bis[4-(p,p′-ditolylamino)phenyl]diphenylsilane) shown above has been used as a carrier-transporting material in organic electroluminescent devices (e.g., U.S. Patent Application Publication No. 2009/0295278). While DTASi exhibits a sufficient T1 (excited triplet) energy (about 2.92 MeV), it also exhibits a high level of crystallinity. As a result, devices incorporating this particular carrier-transport material suffer from a short device lifetime.

In this disclosure, any discussion of problems and solutions involved in the related art has been included solely for the purposes of providing a context for the present invention, and it should not be taken as an admission that any or all of the discussion were known at the time the invention was made.

### SUMMARY

Conventional hole-transport materials in the OLED devices have problems with low triplet energy, a high charge injection barrier, insufficient thin-layer smoothness, and low stability. Some embodiments of the present invention disclose a new series of hole-transport materials, with high carrier mobility, high triplet energy, a low charge injection barrier, good electron blocking effects, excellent amorphous properties, and high stability.

In general, adding an additional phenylene group to a chemical structure is expected to reduce the T1 due to the extended conjugation length, which has been found in literatures with different structures. However, in particularly designed structures, adding an additional phenylene between the amino and tetraphenylsilane, especially through meta-linkage, surprisingly not only retains the high level of T1, but also demonstrates much higher thermal stability than does DTASi.

Some embodiments are related to a compound represented by a formula:

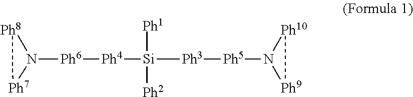

wherein each dashed line indicates an optional bond; and Ph¹, Ph², Ph³, Ph⁴, Ph⁵, Ph⁶, Ph⁷, Ph⁸, Ph⁹, and Ph¹⁰ are independently optionally substituted phenyl.

By employing the above newly designed molecular structure, a new series of hole-transport materials can be used in OLED devices. In some embodiments, this type of material has high photostability, electrostability, and thermal stability, which lead to longer lifetime of the OLED devices. In some embodiments, the biphenyl linker between nitrogen and silicon atoms can be selected from meta-meta, meta-para, or para-meta to infuse the material with an appropriate combination of opto-physical properties for maximum device performance. In some embodiments, when being built into OLED devices, this type of material is shown to have high efficiency and durability.

These and other embodiments are described in greater detail below.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description which follows.

### BRIEF DESCRIPTION OF THE DRAWINGS

These and other features of this invention will now be described with reference to the drawings of preferred embodiments which are intended to illustrate and not to limit the invention. The drawings are oversimplified for illustrative purposes and are not necessarily to scale.

FIG. 1 depicts an exemplary configuration of an embodiment of an OLED device described herein.

FIG. 2 shows the EL spectrum of an OLED device described herein.

FIG. 3 shows the relationship between LE (light efficiency), PE (power efficiency), and B (brightness) of a device described herein.

FIG. 4 shows the relationship between LE (light efficiency), PE (power efficiency), and B (brightness) of a device described herein.

FIG. 5 shows the phosphorescence emission spectrum (measured at 77K) of a compound (Formula 21) described herein.

FIG. 6 shows a proton NMR spectrum (signal intensity in arbitrary units [A.U.] vs. chemical shift in ppm) of a compound (Formula 21) described herein.

FIG. 7 shows a proton NMR spectrum (signal intensity in arbitrary units [A.U.] vs. chemical shift in ppm) of a compound (Formula 22) described herein.

FIG. 8 shows a proton NMR spectrum (signal intensity in arbitrary units [A.U.] vs. chemical shift in ppm) of a compound (Formula 23) described herein.

FIG. 9 shows a proton NMR spectrum (signal intensity in arbitrary units [A.U.] vs. chemical shift in ppm) of a compound (Formula 24) described herein.

FIG. 10 shows a proton NMR spectrum (signal intensity in arbitrary units [A.U.] vs. chemical shift in ppm) of a compound (Formula 25) described herein.

### DETAILED DESCRIPTION OF EMBODIMENTS

Unless otherwise indicated, when a chemical structural feature such as phenyl is referred to as being “optionally substituted,” it includes a feature which may have no substituents (i.e. may be unsubstituted) or which may have one or more substituents. A feature that is “substituted” has one or more substituents. The term “substituent” has the ordinary meaning known to one of ordinary skill in the art. In some embodiments, the substituent includes an ordinary organic moiety known in the art, which may have a molecular weight (e.g. the sum of the atomic masses of the atoms of the substituent) of less than: about 500 g/mol, about 300 g/mol, about 200 g/mol, about 100 g/mol, or about 50 g/mol. In some embodiments, the substituent comprises: about 0-30, about 0-20, about 0-10, or about 0-5 carbon atoms; and about 0-30, about 0-20, about 0-10, or about 0-5 heteroatoms independently selected from: N, O, S, P, Si, F, Cl, Br, I, and combinations thereof; provided that the substituent comprises at least one atom selected from: C, N, O, S, P, Si, F, Cl, Br, and I. Examples of substituents include, but are not limited to, alkyl, alkenyl, alkynyl, carbazolyl, aryl, heteroaryl, heteroalicyclyl, aralkyl, heteroaralkyl, (heteroalicyclyl)alkyl, hydroxy, protected hydroxy, alkoxy, aryloxy, acyl, ester, mercapto, alkylthio, arylthio, cyano, halogen, carbonyl, thiocarbonyl, O-carbamyl, N-carbamyl, O-thiocarbamyl, N-thiocarbamyl, C-amido, N-amido, S-sulfonamido, N-sulfonamido, C-carboxy, protected C-carboxy, O-carboxy, isocyanato, thiocyanato, isothiocyanato, nitro, silyl, sulfenyl, sulfinyl, sulfonyl, haloalkyl, haloalkoxyl, trihalomethanesulfonyl, trihalomethanesulfonamido, and amino, including mono- and di-substituted amino groups, and the protected derivatives thereof. In some embodiments, the substituent may be selected from F, Cl, Br, I, NO₂, —CN, —CNO, —NCO, R′, —OR′, —COR′, —CO₂R′, —OCOR′, —NR′COR″, CONR′R″, —NR′R″, wherein each R′ and R″ is independently H, optionally substituted phenyl, C₁₋₁₂ alkyl, or C₁₋₆ alkyl.

As used herein the term “aryl” has the ordinary meaning understood by a person of ordinary skill in the art, and may include an aromatic ring or aromatic ring system such as phenyl, naphthyl, etc.

As used herein, the term “alkyl” has the ordinary meaning understood by a person of ordinary skill in the art, and may include a moiety composed of carbon and hydrogen containing no double or triple bonds. Alkyl may be linear, branched, cyclic, or a combination thereof, and in some embodiments, may contain from one to thirty-five carbon atoms. Examples of alkyl groups include but are not limited to CH₃ (e.g. methyl), C₂H₅ (e.g. ethyl), C₃H₇ (e.g. propyl isomers such as propyl, isopropyl, etc.), C₃H₆ (e.g. cyclopropyl), C₄H₉ (e.g. butyl isomers) C₄H₈ (e.g. cyclobutyl isomers such as cyclobutyl, methylcyclopropyl, etc.), C₅H₁₁ (e.g. pentyl isomers), C₅H₁₀ (e.g. cyclopentyl isomers such as cyclopentyl, methylcyclobutyl, dimethylcyclopropyl, etc.) C₆H₁₃ (e.g. hexyl isomers), C₆H₁₂ (e.g. cyclohexyl isomers), C₇H₁₅ (e.g. heptyl isomers), C₇H₁₄ (e.g. cycloheptyl isomers), C₈H₁₇ (e.g. octyl isomers), C₈H₁₆ (e.g. cyclooctyl isomers), C₉H₁₉ (e.g. nonyl isomers), C₉H₁₈ (e.g. cyclononyl isomers), C₁₀H₂₁ (e.g. decyl isomers), C₁₀H₂O (e.g. cyclodecyl isomers), C₁₁H₂₃ (e.g. undecyl isomers), C₁₁H₂₂ (e.g. cycloundecyl isomers), C₁₂H₂₅ (e.g. dodecyl isomers), C₁₂H₂₄ (e.g. cyclododecyl isomers), C₁₃H₂₇ (e.g. tridecyl isomers), C₁₃H₂₆ (e.g. cyclotridecyl isomers), and the like.

An expression such as “C₁₋₁₀” (e.g. “C₁₋₁₀ alkyl”) or “C₆₋₁₀” (e.g. “C₆₋₁₀ aryl”) refers to the number of carbon atoms in a moiety, and similar expressions have similar meanings If a moiety is optionally substituted, such as “optionally substituted “C₆₋₁₀ aryl,” the designation of the number of carbon atoms such as “C₆₋₁₀” refers to the parent moiety only (e.g. the ring carbons of aryl) and does not characterize or limit any substituent on the moiety.

The structures of some of the optionally substituted ring systems referred to herein are depicted below. These ring systems may be unsubstituted, as shown below, or a substituent may independently be in any position normally occupied by a hydrogen atom when the ring system is unsubstituted.

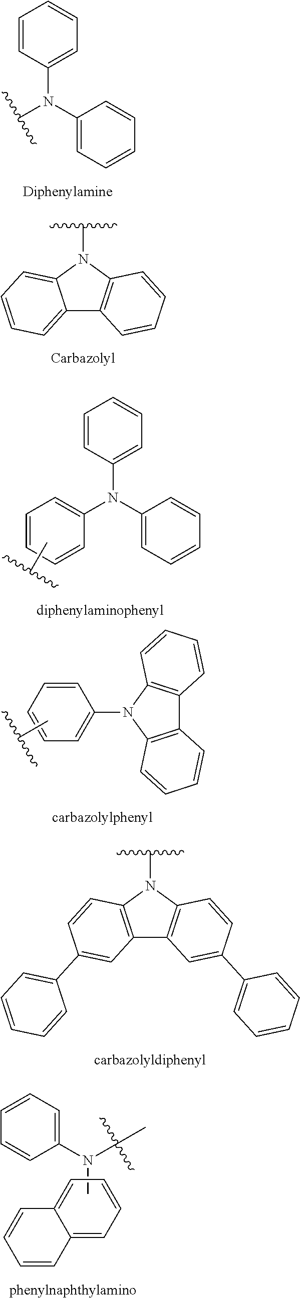

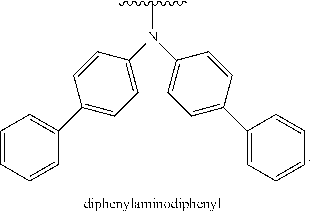

The structures and names of some of the ring systems referred to herein are depicted below. If optionally substituted, these ring systems may be unsubstituted, as shown below, or a substituent may independently be in any position normally occupied by a hydrogen atom.

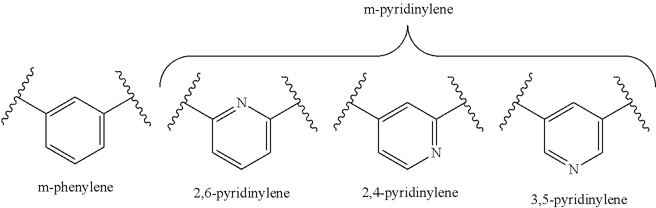

With respect to m-pyridinylene, the term encompasses several isomers, three of which are depicted above.

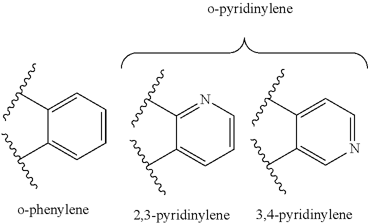

With respect to o-pyridinylene, the term encompasses several isomers, two of which are depicted above.

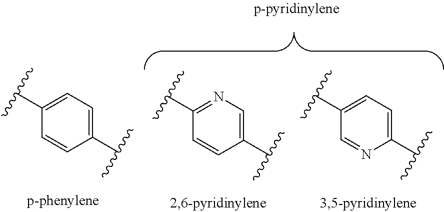

With respect to p-pyridinylene, the term encompasses several isomers, two of which are depicted above

The term “low work function” has the ordinary meaning known to one of ordinary skill in the art. In some embodiments, a “work function” of a metal is a measure of the minimum energy required to extract an electron from the surface of the metal.

The term “high work function” has the ordinary meaning known to one of ordinary skill in the art, and may include a metal or alloy that easily injects holes and typically has a work function greater than or equal to about 4.5 eV.

The term “low work function metal” has the ordinary meaning known to one of ordinary skill in the art, and may include a metal or alloy that easily loses electrons and typically has a work function less than about 4.3 eV.

In some embodiments, “film” refers to a layer continuously extending in a direction perpendicular to a thickness direction substantially without pinholes to cover an entire target or concerned surface, or simply a layer covering a target or concerned surface. In some embodiments, “layer” refers to a structure having a certain thickness formed on a surface or a synonym of film. A film or layer may be constituted by a discrete single film or layer having certain characteristics or multiple films or layers, and a boundary between adjacent films or layers may or may not be clear and may be established based on physical, chemical, and/or any other characteristics, formation processes or sequence, and/or functions or purposes of the adjacent films or layers. In this disclosure, any defined meanings do not necessarily exclude ordinary and customary meanings in some embodiments. Further, in this disclosure, any ranges indicated may include or exclude the endpoints.

Some embodiments relate to compounds represented by at least one of Formulas 1-25.

Surprisingly, the 3,3′-bis[3-(di-p-tolylamino)benzene]tetraphenylsilane type material, for example, has high hole-transporting mobility and high triplet energy, and can be a very efficient hole-transport, electron-blocking, and/or excitation blocking material in the OLED devices. Another advantage observed in some embodiments is an improved thin-layer interfacial smoothness which is hypothesized to contribute to the high efficiency in devices employing these materials.

In some embodiments, the compound has the following formula:

Hcy-(Ph)₂-Sia-(Ph)₂-Hcy (Formula 2)
wherein Sia is an optionally substituted diphenylsilane; Ph is selected from optionally substituted p-phenylene and optionally substituted m-phenylene; Hcy is selected from optionally substituted m-carbazolyl and optionally substituted m-arylamine, optionally substituted p-carbazolyl and optionally substituted p-arylamine, wherein at least one of Ph-Sia and Hcy-Ph are meta-linked.

In some embodiments, a charge transporting compound includes an Hcy is selected from optionally substituted carbazol-9-yl and optionally substituted diphenylamine. In some embodiments this invention comprises a charge transporting compound represented by Formula 3:

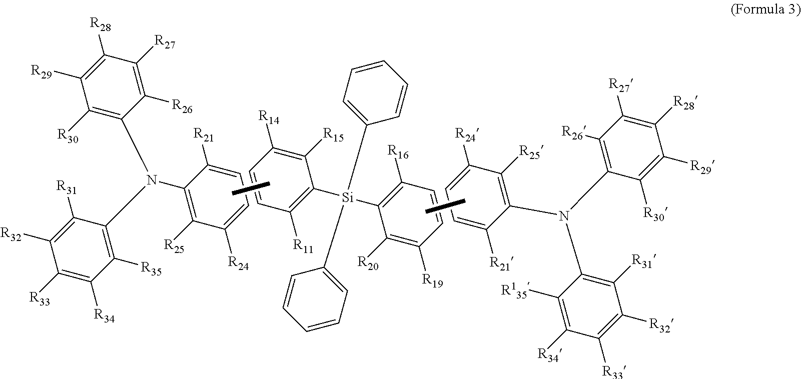

wherein each bold line is independently a meta- or para-bond between adjacent 6-member cyclic groups, thus the biphenyl bridge between nitrogen and silicon atoms can be optionally arranged as meta-meta, meta-para, or para-meta. In some other embodiments, R₁₄₋₃₅, and R_{21′-35′}, can be independently substituted with hydrogen or C₁-C₆ alkyl. In some embodiments, in R₁₄-R₂₀, adjacent R groups can form a 5- or 6-member aromatic ring group (e.g. cyclopentadienyl or carbazolyl) which may be optionally substituted with hydrogen or C₁-C₆ alkyl.

In some embodiments, the compound comprises a diphenylsilane core selected from:

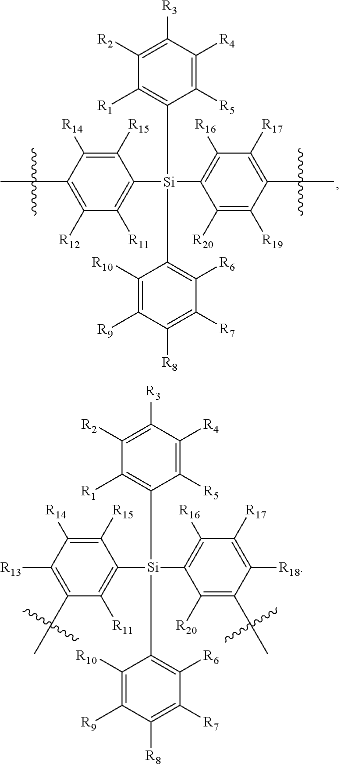

In some embodiments, R₁-R₂₀ are independently selected from hydrogen, C₁-C₆ alkyl, C₁-C₆ alkoxy, C₆-C₁₂ aryl ether, C₁-C₁₂ alkyl-substituted aryl ether, C₂-C₆ olefin having a degree of unsaturation from 1-6, C₄-C₁₈ heterocycle containing nitrogen, oxygen, and/or sulfur atoms which can be optionally substituted with alkyl or aryl groups. In some embodiments, the C₂-C₆ olefin having a degree of unsaturation from 1-6 is selected from a vinyl group. In some embodiments, R₁-R₁₀ are hydrogen. In some embodiments, R₁₁-R₂₀ are hydrogen. In some embodiments, R₁-R₂₀ are hydrogen.

In some embodiments, R₁-R₁₀ R₁₁, R₁₅, R₁₆, and R₂₀ are hydrogen and R₁₂, R₁₄, R₁₇ and R₁₉ are methyl.

In some embodiments, Hcy is selected from:

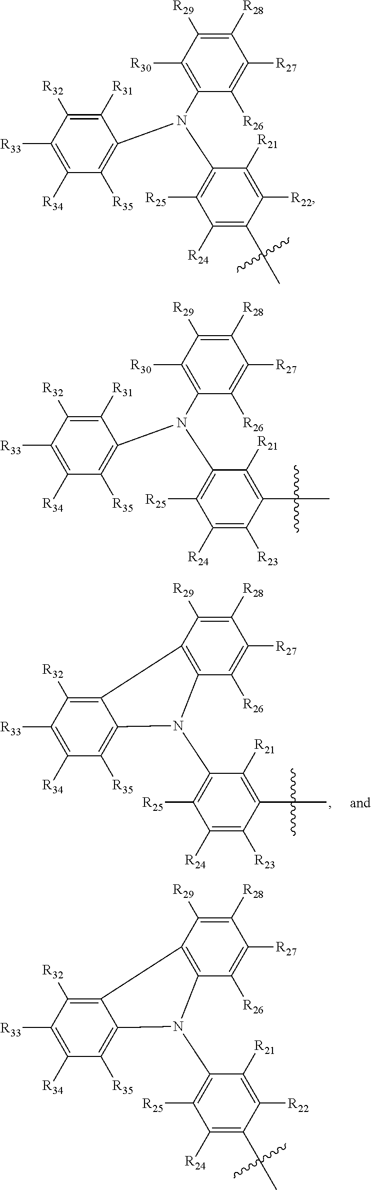

wherein R₂₁-R₃₅ are selected from hydrogen and C₁-C₆ alkyl. In some embodiments, R₂₁-R₃₅ are hydrogen. In some embodiments, R₁-R₁₀ are hydrogen; and R₂₁-R₂₉ and R₃₂-R₃₅ are selected from hydrogen and —CH₃; and R₃₀ and R₃₁ are selected from a bond connecting R₃₀ and R₃₁ and hydrogen.

In one embodiment, the diphenylsilane core is substituted with a group selected from

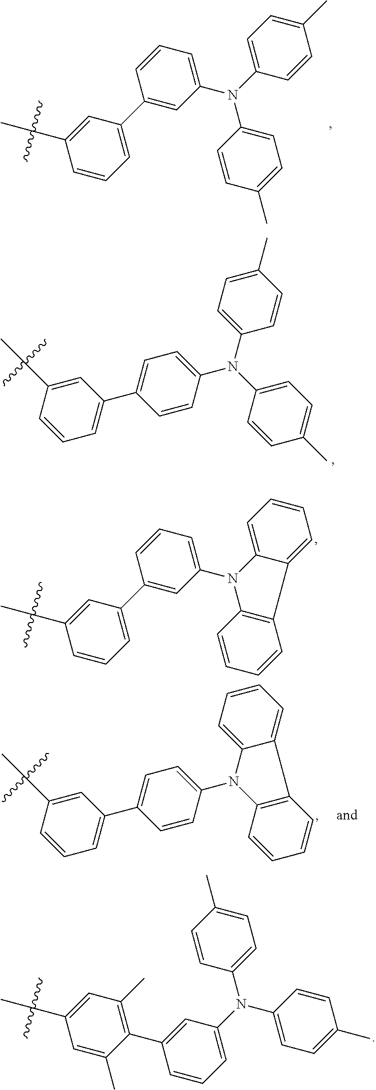

The disclosed chemical structures include:

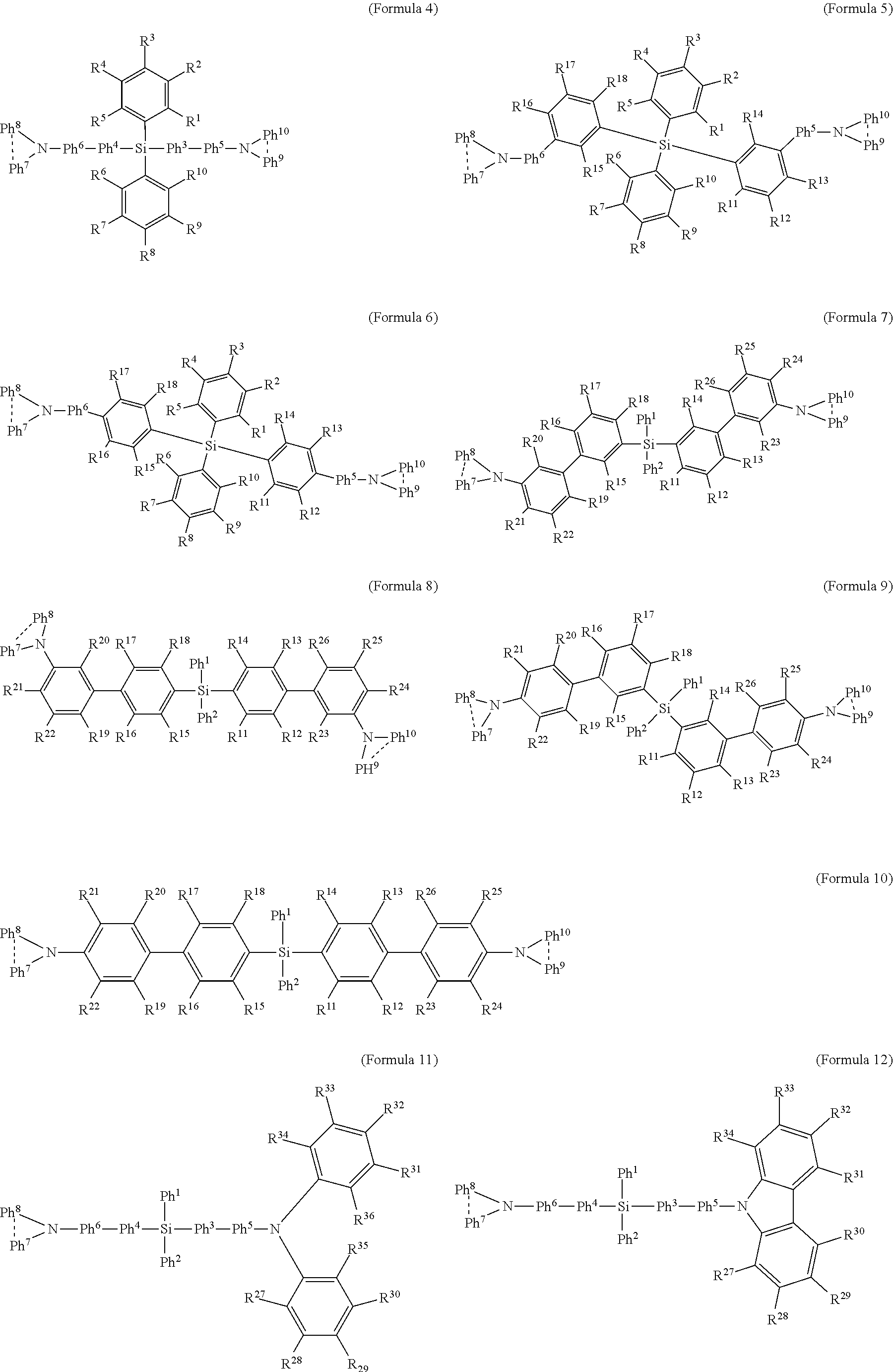

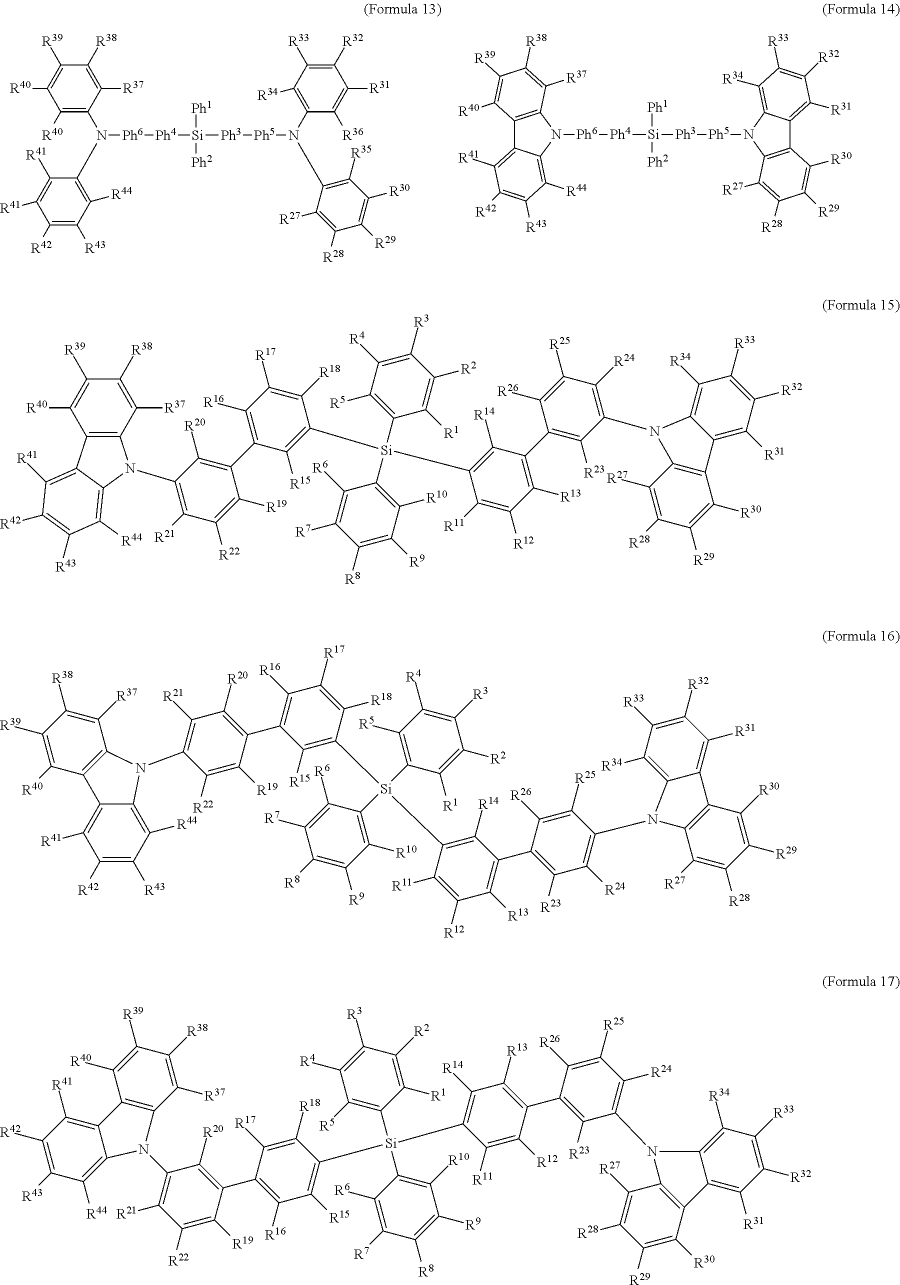

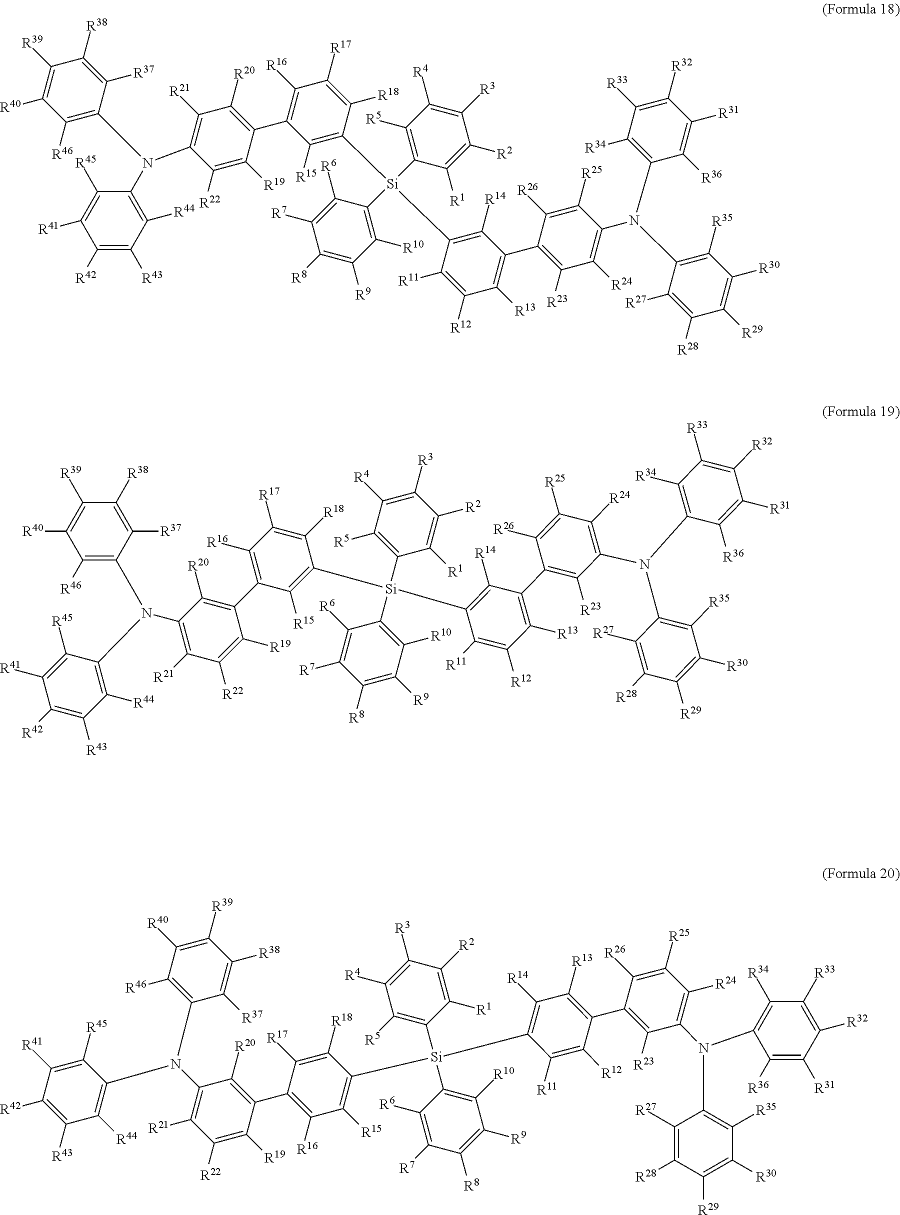

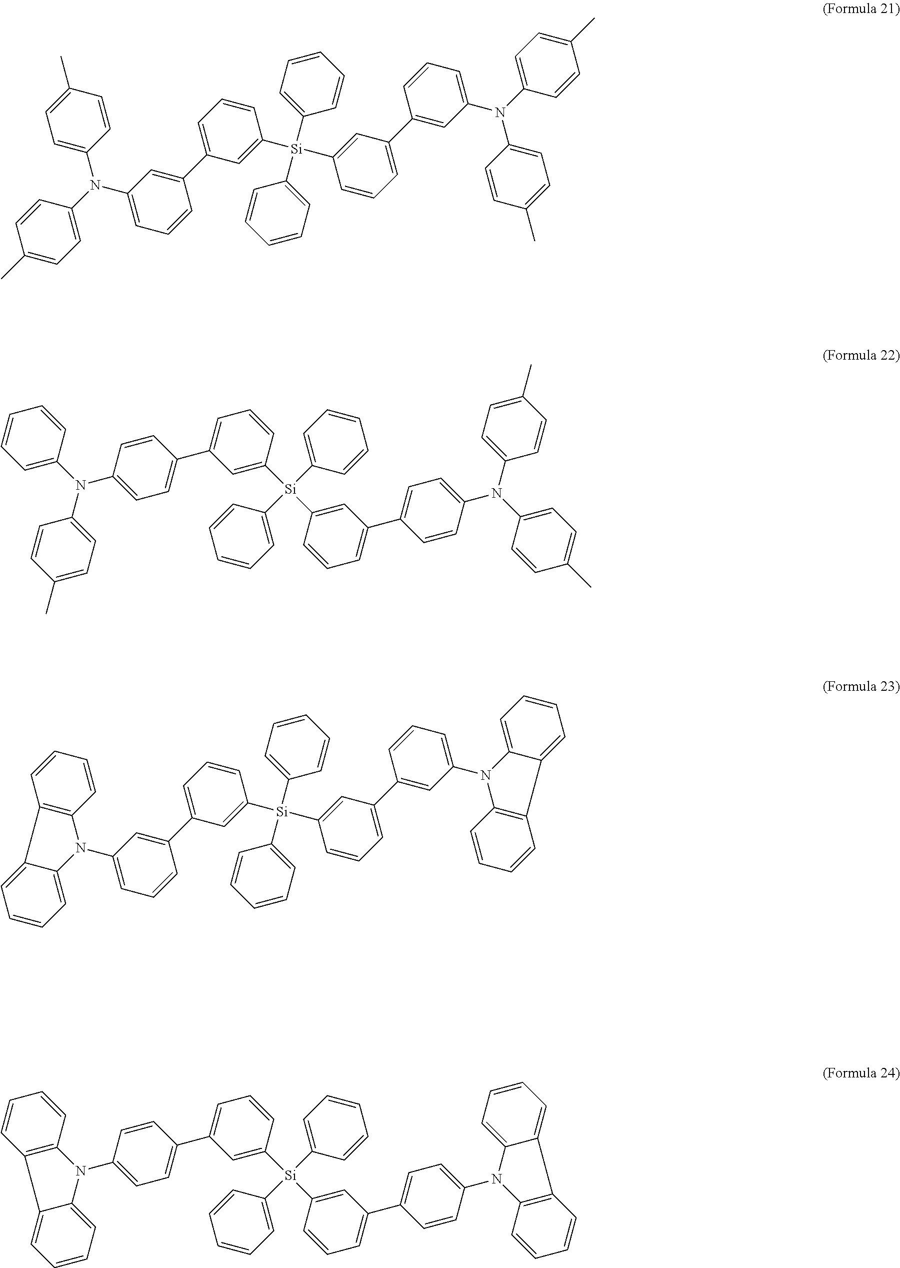

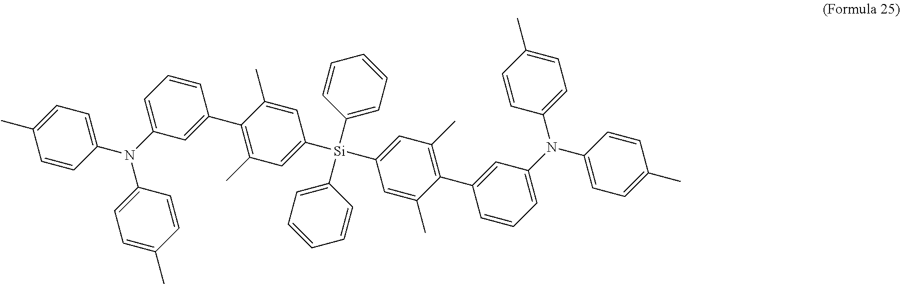

In the above, with respect to any relevant formula above, in some embodiments, each dashed line indicates an optional bond; and Ph¹ to Ph¹⁰ are independently optionally substituted phenyl or phenylene. In some embodiments, with respect to any relevant formula above, R¹ to R⁴⁶ are independently R^{a} or —OR^{a}, wherein each R^{a} is independently H, C₁₋₆ hydrocarbyl, optionally substituted C₆₋₁₂ aryl, or an optionally substituted C₄₋₁₈ heterocycle. In some embodiments, at least one R^{a} is vinyl. In some embodiments, with respect to any relevant formula, R¹ to R¹⁰ are H, and R¹¹ to R⁴⁶ are independently selected from —CH₃ or H. In some embodiments, with respect to any relevant formula above, R¹ to R¹⁸ are independently selected from H, —CH₃, and —C₂H₅. In some embodiments, with respect to any relevant formula, R¹⁹ to R⁴⁶ are independently selected from the group consisting of H, F, Cl, Br, I, —CN, C₁₋₁₂ alkyl, C₁₋₆ alkyl, C₁₋₁₂ fluoroalkyl, C₁₋₆ fluoroalkyl, optionally substituted C₆₋₁₀ aryl and optionally substituted phenyl. In some embodiments, with respect to any relevant formula, Ph⁵ and Ph⁶ are independently m-phenylene or p-phenylene, and Ph⁵, Ph⁶, Ph⁷, Ph⁸, Ph⁹, and Ph¹⁰ are independently unsubstituted phenyl, or phenyl having 1, 2, 3, or 4 C₁₋₆ alkyl substituents. In some embodiments, with respect to any relevant formula, Ph¹ and Ph² are unsubstituted phenyl; and, Ph³, Ph⁴, Ph⁵, Ph⁶, Ph⁷, Ph⁸, Ph⁹, and Ph¹⁰ are independently unsubstituted phenyl, or phenyl having 1, 2, 3, or 4 methyl substituents.

The compounds included in Formula 1 can be synthesized based on a reaction scheme including, but not limited to, the following:

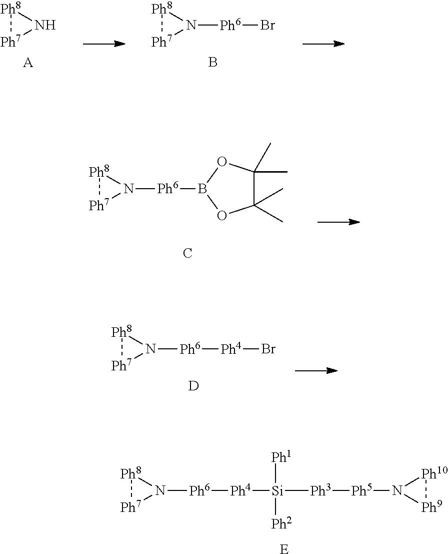

Compound A, iodobromobenzene, [1,1′-bis(diphenylphosphino)ferrocene]dichloropalladium(II), and sodium t-butoxide are mixed and heated at, e.g., 70° after toluene is added, thereby synthesizing Compound B. Compound B, bis(pinacolato)diboron, and [1,1′-bis(diphenylphosphino)ferrocene]dichloropalladium(II) are mixed and heated at, e.g., 80° C. after 1,4-dioxane is added, thereby synthesizing Compound C. Compound C, iodobromobenzene, potassium carbonate, tetrakis(triphenylphosphino)palladium(0), and 1,4-dioxane are mixed and heated at, e.g., 90° C., thereby synthesizing Compound D (for Formula 25, Compound C and 4-bromo-2,6-dimethylphenyl-1-trifluoromethanesulfonate were used to make Compound D in the Synthesis Example 1 described later). After Compound D is dissolved in anhydrous tetrahydrofuran and cooled to, e.g., −78° C., the solution is mixed with n-butylithium and diphenyldichlorosilane, followed by stirring, thereby synthesizing Compound E.

An alternative synthesis scheme is as follows:

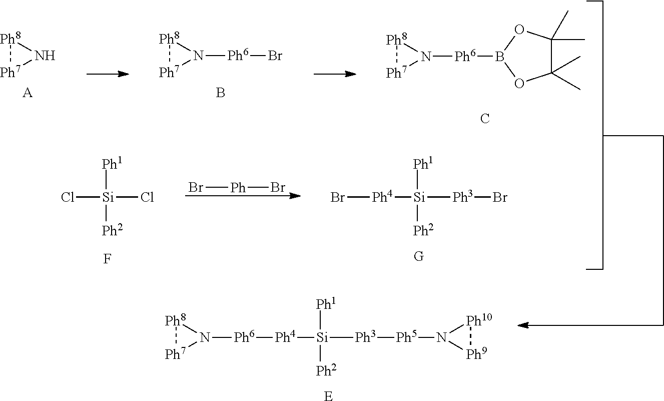

1,3-dibromobenzene is dissolved in anhydrous tetrahydrofuran, and mixed with n-butylithium and stirred at, e.g., −78° C., followed by reacting with Compound F, thereby synthesizing Compound G. Compound C, Compound G, potassium carbonate, tetrakis(triphenylphosphino)palladium(0), and 1,4-dioxane are mixed and reacted, thereby synthesizing Compound E.

By selecting the starting materials according to the final compound, any desired final compounds can be obtained. Any other derivatives can be synthesized via schemes similar to the above. Specific synthesis examples are shown in the Example section, and in the present disclosure where conditions and/or structures are not specified, the skilled artisan in the art can readily provide such conditions and/or structures, in view of the present disclosure, as a matter of routine experimentation.

Preferably the substituents and geometry about the biphenyl bridges are selected to provide a hole-transporting compound that provides the desired HOMO (highest occupied molecular orbital)/LUMO (lowest unoccupied molecular orbital) range and triplet energy. If the substituent linked to the amino group, e.g., arylamino, affects the N-group of the di-p-tolylamino or carbazolyl group by increasing its electron richness, e.g., by substituting with a group comprising a —O—, —S— or another —N—, the resulting compound's HOMO/LUMO values are greater (less negative) than e.g., −5.0 meV, and are not within the preferred range limits, e.g., HOMO value of about −5.1 to about −5.8 eV.

In some embodiments, the materials have high stability and high carrier mobility, are built into OLED devices, and show high power efficiency (greater than 401 m/W).

The compounds and compositions described herein can be incorporated into light-emitting devices in various ways. For example, an embodiment provides an organic component disposed between, and electrically connected to, an anode and a cathode. The organic component comprises the compounds and/or compositions described herein. In some embodiments, the total thickness of the emissive, hole-transport, and emissive layers is about one-quarter (or about 20% to about 35%) of the emissive wavelength, e.g., if the emissive wavelength is about 450 nm, the total thickness of the plurality of layers (emissive layer[s], hole-transport and electron transport layers) is about 100 to about 150 nm.

The anode may be a layer comprising a conventional material such as a metal, mixed metal, alloy, metal oxide or mixed-metal oxide, conductive polymer, and/or an inorganic material such as carbon nanotube (CNT). Examples of suitable metals include the Group 1 metals, the metals in Groups 4, 5, 6, and the Group 8-10 transition metals. If the anode layer is to be light-transmitting, metals in Group 10 and 11, such as Au, Pt, and Ag, or alloys thereof; or mixed-metal oxides of Group 12, 13, and 14 metals, such as indium-tin-oxide (ITO), indium-zinc-oxide (IZO), and the like, may be used. In some embodiments, the anode layer may be an organic material such as polyaniline. The use of polyaniline is described in “Flexible light-emitting diodes made from soluble conducting polymer,” Nature, vol. 357, pp. 477-479 (11 Jun. 1992) (the disclosure of which is herein incorporated by reference). Examples of suitable high work function metals and metal oxides include but are not limited to Au, Pt, or alloys thereof; ITO; IZO; and the like. In some embodiments, the anode layer can have a thickness in the range of about 1 nm to about 1000 nm.

A cathode may be a layer including a material having a lower work function than the anode layer. Examples of suitable materials for the cathode layer include those selected from alkali metals of Group 1, Group 2 metals, Group 12 metals including rare earth elements, lanthanides and actinides, materials such as aluminum, indium, calcium, barium, samarium and magnesium, and combinations thereof. Li-containing organometallic compounds, LiF, and Li₂O may also be deposited between the organic layer and the cathode layer to lower the operating voltage. Suitable low work function metals include but are not limited to Al, Ag, Mg, Ca, Cu, Mg/Ag, LiF/Al, CsF, CsF/Al or alloys thereof. In an embodiment, the cathode layer can have a thickness in the range of about 1 nm to about 1000 nm.

In some embodiments, the organic component may comprise at least one emissive layer comprising an emissive component, and optionally, a host, such as a compound described herein, a hole-transport material, an electron-transport material, or an ambipolar material. If present, the amount of the host in an emissive layer can vary. In one embodiment, the amount of a host in an emissive layer is in the range of from about 50% to about 99.9% by weight of the emissive layer. In another embodiment, the amount of a host in an emissive layer is in the range of from about 90% to about 99% by weight of the emissive layer. In another embodiment, the amount of a host in an emissive layer is about 97% by weight of the emissive layer. In some embodiments, the mass of the emissive component is about 0.1% to about 10%, about 1% to about 5%, or about 3% of the mass of the emissive layer. In some embodiments, the emissive component comprises a fluorescent compound or a phosphorescent compound.

The light-emitting component or compound may be chosen to vary the color of the light emitted by the light-emitting device. For example, a blue light-emitting component may emit a combination of visible photons so that the light appears to have a blue quality to an observer. In some embodiments, a blue light-emitting component may emit visible photons having an average wavelength in the range of about 440 nm or about 460 nm to about 490 nm or about 500 nm. The “average wavelength” of visible photons may include, when referring to the visible emission spectrum of a compound, the wavelength wherein the area under the curve for the part of the visible spectrum having a lower wavelength than the average wavelength is about equal to the area under the curve for the part of the visible spectrum having a higher wavelength than the average wavelength. Some non-limiting examples of compounds which may form part or all of a blue light-emitting component include iridium coordination compounds such as: bis-{2-[3,5-bis(trifluoromethyl)phenyl]pyridinato-N,C2′}iridium(III)-picolinate, bis(2-[4,6-difluorophenyl]pyridinato-N,C2′)iridium (III) picolinate, bis(2-[4,6-difluorophenyl]pyridinato-N,C2′)iridium(acetylacetonate), Iridium (III) bis(4,6-difluorophenylpyridinato)-3-(trifluoromethyl)-5-(pyridine-2-yl)-1,2,4-triazolate, Iridium (III) bis(4,6-difluorophenylpyridinato)-5-(pyridine-2-yl)-1H-tetrazolate, bis[2-(4,6-difluorophenyl)pyridinato-N,C^{2′}]iridium(III)tetra(1-pyrazolyl)borate, etc.

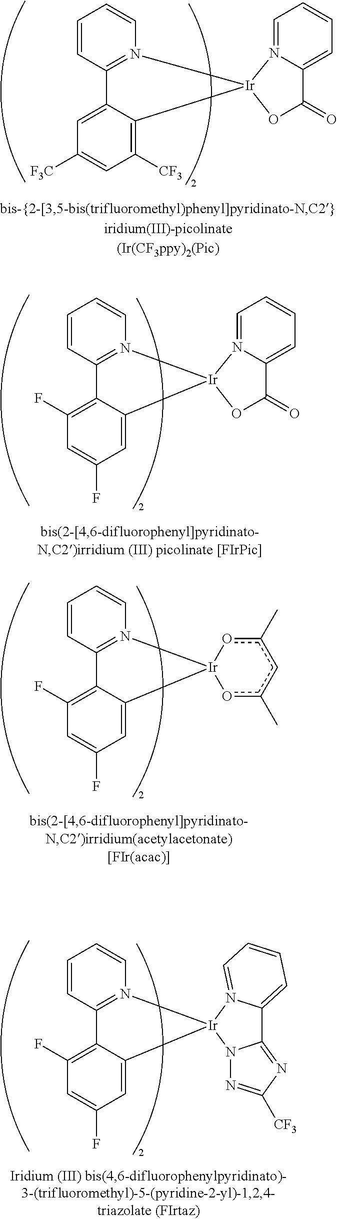

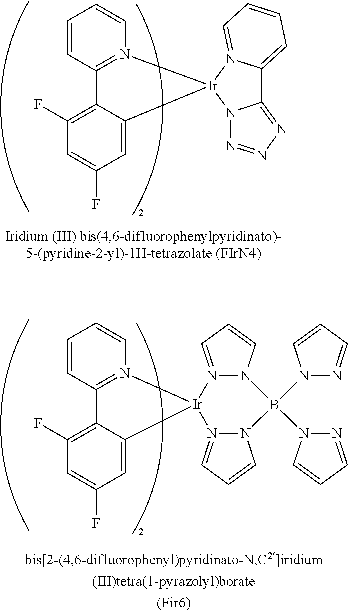

A red light-emitting component may emit a combination of visible photons so that the light appears to have a red quality to an observer. In some embodiments, a red light-emitting component may emit visible photons having an average wavelength in the range of about 600 nm or about 620 nm to about 780 nm or about 800 nm (this is NIR light). Some non-limiting examples of compounds which may form part or all of a red light-emitting component include iridium coordination compounds such as: Bis[2-(2′-benzothienyl)-pyridinato-N,C3′] iridium (III)(acetylacetonate); Bis[(2-phenylquinolyl)-N,C2′]iridium (III) (acetylacetonate); Bis[(1-phenylisoquinolinato-N,C2′)]iridium (III) (acetylacetonate); Bis[(dibenzo[f,h]quinoxalino-N,C2′)iridium (III)(acetylacetonate); Tris(2,5-bis-2′-(9′,9′-dihexylfluorene)pyridine)iridium (III); Tris[1-phenylisoquinolinato-N,C2′]iridium (III); Tris-[2-(2′-benzothienyl)-pyridinato-N,C3′] iridium (III); Tris[1-thiophen-2-ylisoquinolinato-N,C3′]iridium (III); and Tris[1-(9,9-dimethyl-9H-fluoren-2-yl)isoquinolinato-(N,C3′)iridium (III)), etc.

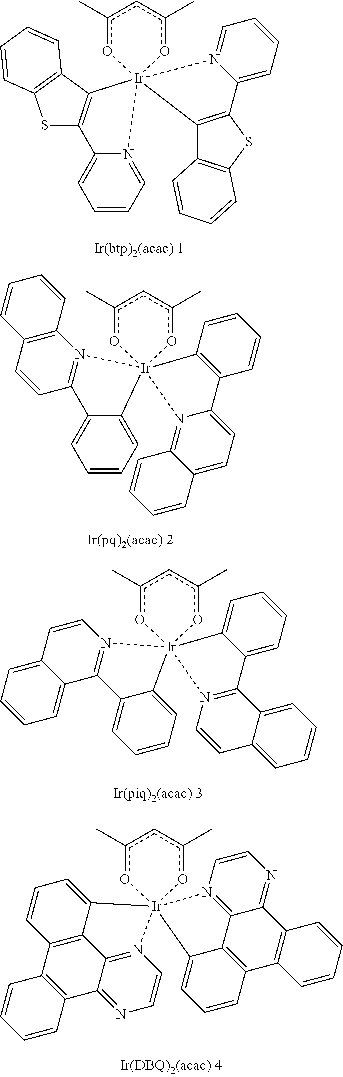

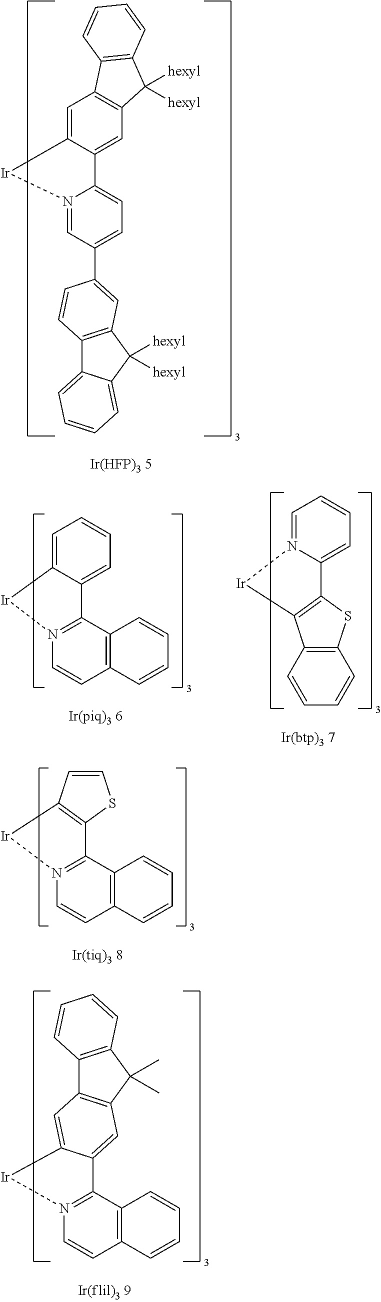

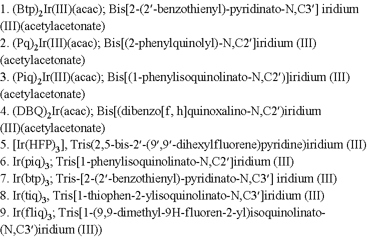

A green light-emitting component may emit a combination of visible photons so that the light appears to have a green quality to an observer. In some embodiments, a green light-emitting component may emit visible photons having an average wavelength in the range of about 490 nm or about 500 nm to about 570 nm or about 600 nm. Some non-limiting examples of compounds which may form part or all of a green light-emitting component include iridium coordination compounds such as: Bis(2-phenylpyridinato-N,C2′)iridium(III)(acetylacetonate) [Ir(ppy)₂(acac)], Bis(2-(4-tolyl)pyridinato-N,C2′)iridium(III)(acetylacetonate) [Ir(mppy)₂(acac)], Bis(2-(4-tert-butyl)pyridinato-N,C2′)iridium (III)(acetylacetonate) [Ir(t-Buppy)₂(acac)], Tris(2-phenylpyridinato-N,C2′)iridium (III) [Ir(ppy)₃], Bis(2-phenyloxazolinato-N,C2′)iridium (III) (acetylacetonate) [Ir(op)₂(acac)], Tris(2-(4-tolyl)pyridinato-N,C2′)iridium(III) [Ir(mppy)₃], etc.

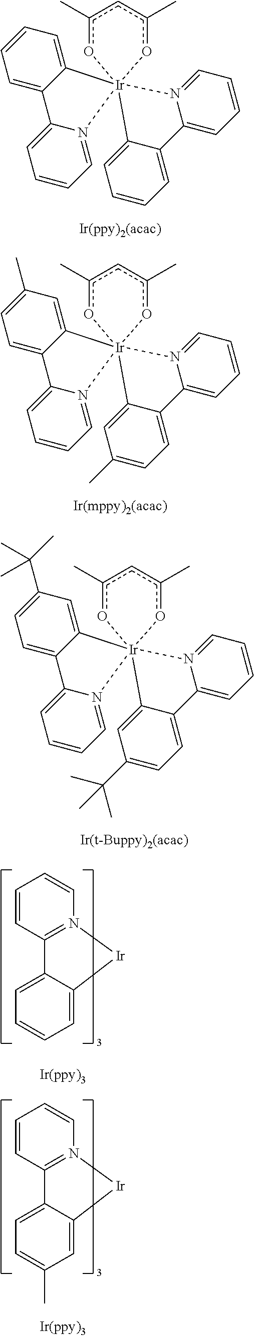

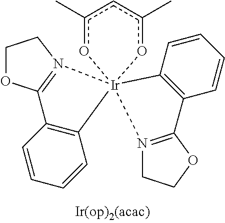

An orange light-emitting component may emit a combination of visible photons so that the light appears to have an orange quality to an observer. In some embodiments, an orange light-emitting component may emit visible photons having an average wavelength in the range of about 570 nm or about 585 nm to about 620 nm or about 650 nm. Some non-limiting examples of compounds which may form part or all of an orange light-emitting component include iridium coordination compounds such as: Bis[2-phenylbenzothiazolato-N,C2′] iridium (III)(acetylacetonate), Bis[2-(4-tert-butylphenyl)benzothiazolato-N,C2′]iridium(III)(acetylacetonate), Bis[(2-(2′-thienyl)pyridinato-N,C3′)]iridium (III) (acetylacetonate), Tris[2-(9.9-dimethylfluoren-2-yl)pyridinato-(N,C3′)]iridium (III), Tris[2-(9.9-dimethylfluoren-2-yl)pyridinato-(N,C3′)]iridium (III), Bis[5-trifluoromethyl-2-[3-(N-phenylcarbzolyl)pyridinato-N,C2′]iridium(III)(acetylacetonate), (2-PhPyCz)₂Ir(III)(acac), etc.

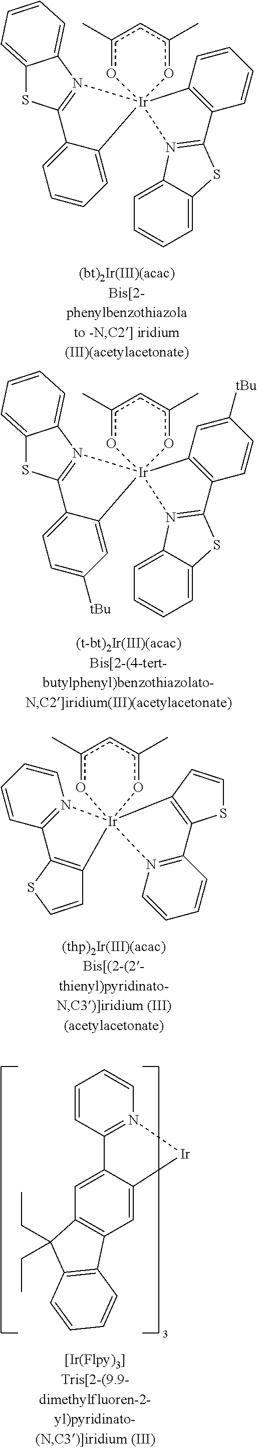

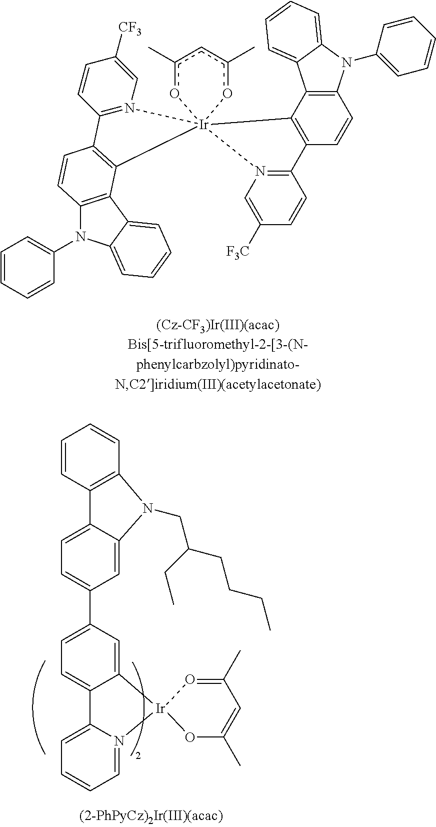

The thickness of an emissive layer may vary. In one embodiment, an emissive layer has a thickness in the range of from about 1 nm to about 150 nm or about 200 nm. In another embodiment, an emissive layer has a thickness in the range of about 1 nm to about 150 nm. The emissive layer may comprise a host material and any light-emitting component disclosed herein or any other suitable component, wherein the weight ratio of the light-emitting component to the host material may be in a range of about 1% to about 20% or about 5% to about 10%.

In some embodiments, the light-emitting device may emit white light. An emissive layer may be configured to emit white light by including a white light emitter, or a combination of colored emitters which have a combined emission that appears white. Alternatively, a combination of different colored emissive layers may be configured to emit white light.

In some embodiments, the organic component may further comprise a hole-transport layer disposed between the anode and the emissive layer. In some embodiments, the thickness of the hole-transport layer may be in a range of about 10 nm to about 150 nm. The hole-transport layer may comprise at least one hole-transport material which comprises or consists essentially of one compound or two or more compounds represented by Formula 1. In some embodiments, the hole-transport material comprises at least one of the compounds represented by any of Formulas 2-25. In some embodiments, the compounds represented by any of Formulas 1-25 may account for about 50% to about 100% by weight of the total weight of the hole-transport layer.

In some embodiments, the hole-transport layer may further comprise, in addition to the compounds represented by Formula 1, an aromatic-substituted amine, a carbazole, a polyvinylcarbazole (PVK), e.g. poly(9-vinylcarbazole); polyfluorene; a polyfluorene copolymer; poly(9,9-di-n-octylfluorene-alt-benzothiadiazole); poly(paraphenylene); poly[2-(5-cyano-5-methylhexyloxy)-1,4-phenylene]; a benzidine; a phenylenediamine; a phthalocyanine metal complex; a polyacetylene; a polythiophene; a triphenylamine; an oxadiazole; copper phthalocyanine; 1,1-Bis(4-bis(4-methylphenyl)aminophenyl)cyclohexane; 2,9-Dimethyl-4,7-diphenyl-1,10-phenanthroline; 3,5-Bis(4-tert-butyl-phenyl)-4-phenyl[1,2,4]triazole; 3,4,5-Triphenyl-1,2,3-triazole; 4,4′,4′-tris(3-methylphenylphenylamino)triphenylamine (MTDATA); N,N′-bis(3-methylphenyl)N,N′-diphenyl-[1,1′-biphenyl]-4,4′-diamine (TPD); 4,4′-bis[N-(naphthyl)-N-phenyl-amino]biphenyl (α-NPD); 4,4′,4″-tris(carbazol-9-yl)-triphenylamine (TCTA); 4,4′-bis[N,N′-(3-tolyl)amino]-3,3′-dimethylbiphenyl (HMTPD); 4,4′-N,N′-dicarbazole-biphenyl (CBP); 1,3-N,N-dicarbazole-benzene (mCP); Bis[4-(p,p′-ditolyl-amino)phenyl]diphenylsilane (DTASi); 2,2′-bis(4-carbazolylphenyl)-1,1′-biphenyl (4CzPBP); N,N′N″-1,3,5-tricarbazoloylbenzene (tCP); N,N′-bis(4-butylphenyl)-N,N′-bis(phenyl)benzidine; or the like.

In some embodiments, the organic component may further comprise an electron-transport layer disposed between the cathode and the emissive layer. In some embodiments, the electron-transport layer may comprise a compound described herein such as those represented by Formula 1. Other electron-transport materials may be included, such as 2-(4-biphenylyl)-5-(4-tert-butylphenyl)-1,3,4-oxadiazole (PBD); 1,3-bis(N,N-t-butyl-phenyl)-1,3,4-oxadiazole (OXD-7), 1,3-bis[2-(2,2′-bipyridine-6-yl)-1,3,4-oxadiazo-5-yl]benzene; 3-phenyl-4-(1′-naphthyl)-5-phenyl-1,2,4-triazole (TAZ); 2,9-dimethyl-4,7-diphenyl-phenanthroline (bathocuproine or BCP); aluminum tris(8-hydroxyquinolate) (Alq3); and 1,3,5-tris(2-N-phenylbenzimidazolyl)benzene; 1,3-bis[2-(2,2′-bipyridine-6-yl)-1,3,4-oxadiazo-5-yl]benzene (BPY-OXD); 3-phenyl-4-(1′-naphthyl)-5-phenyl-1,2,4-triazole (TAZ),2,9-dimethyl-4,7-diphenyl-phenanthroline (bathocuproine or BCP); and 1,3,5-tris[2-N-phenylbenzimidazol-z-yl]benzene (TPBI). In one embodiment, the electron transport layer is aluminum quinolate (Alq₃), 2-(4-biphenylyl)-5-(4-tert-butylphenyl)-1,3,4-oxadiazole (PBD), phenanthroline, quinoxaline, 1,3,5-tris[N-phenylbenzimidazol-z-yl] benzene (TPBI), or a derivative or a combination thereof.

If desired, additional layers may be included in the light-emitting device. These additional layers may include an electron injection layer (EIL), a hole-blocking layer (HBL), an exciton-blocking layer (EBL), and/or a hole-injection layer (HIL). In addition to separate layers, some of these materials may be combined into a single layer. In some embodiments, the thickness of each of the above layers or any relevant layer may be in a range of a few nm to about 150 nm.

In some embodiments, the light-emitting device can include an electron-injection layer between the cathode layer and the emissive layer. In some embodiments, the electron-injection layer may comprise a compound described herein. Other suitable electron injection materials may also be included, and are known to those skilled in the art. Examples of suitable material(s) that can be included in the electron injection layer include but are not limited to, an optionally substituted compound selected from the following: aluminum quinolate (Alq₃), 2-(4-biphenylyl)-5-(4-tert-butylphenyl)-1,3,4-oxadiazole (PBD), phenanthroline, quinoxaline, 1,3,5-tris[N-phenylbenzimidazol-z-yl] benzene (TPBI) a triazine, a metal chelate of 8-hydroxyquinoline such as tris(8-hydroxyquinoliate) aluminum, and a metal thioxinoid compound such as bis(8-quinolinethiolato) zinc. In one embodiment, the electron injection layer is aluminum quinolate (Alq₃), 2-(4-biphenylyl)-5-(4-tert-butylphenyl)-1,3,4-oxadiazole (PBD), phenanthroline, quinoxaline, 1,3,5-tris[N-phenylbenzimidazol-z-yl] benzene (TPBI), or a derivative or a combination thereof.

In some embodiments, the device can include a hole-blocking layer, e.g., between the cathode and the emissive layer. Various suitable hole-blocking materials that can be included in the hole-blocking layer are known to those skilled in the art. Suitable hole-blocking material(s) include but are not limited to, an optionally substituted compound selected from the following: bathocuproine (BCP), 3,4,5-triphenyl-1,2,4-triazole, 3,5-bis(4-tert-butyl-phenyl)-4-phenyl-[1,2,4]triazole, 2,9-dimethyl-4,7-diphenyl-1,10-phenanthroline, and 1,1-bis(4-bis(4-methylphenyl)aminophenyl)-cyclohexane.

In some embodiments, the light-emitting device can include an exciton-blocking layer, e.g., between the emissive layer and the anode. In an embodiment, the band gap of the material(s) that comprise an exciton-blocking layer is large enough to substantially prevent the diffusion of excitons. A number of suitable exciton-blocking materials that can be included in the exciton-blocking layer are known to those skilled in the art. Examples of material(s) that can compose an exciton-blocking layer include an optionally substituted compound selected from the following: aluminum quinolate (Alq₃), 4,4′-bis[N-(naphthyl)-N-phenyl-amino]biphenyl (α-NPD), 4,4′-N,N′-dicarbazole-biphenyl (CBP), and bathocuproine (BCP), and any other material(s) that have a large enough band gap to substantially prevent the diffusion of excitons.

In some embodiments, the light-emitting device can include a hole-injection layer, e.g., between the emissive layer and the anode. Various suitable hole-injection materials that can be included in the hole-injection layer are known to those skilled in the art. Exemplary hole-injection material(s) include an optionally substituted compound selected from the following: a polythiophene derivative such as poly(3,4-ethylenedioxythiophene (PEDOT)/polystyrene sulphonic acid (PSS), a benzidine derivative such as N,N,N′, N′-tetraphenylbenzidine, poly(N,N′-bis(4-butylphenyl)-N,N′-bis(phenyl)benzidine), a triphenylamine or phenylenediamine derivative such as N,N′-bis(4-methylphenyl)-N,N′-bis(phenyl)-1,4-phenylenediamine, 4,4′,4″-tris(N-(naphthylen-2-yl)-N-phenylamino)triphenylamine, an oxadiazole derivative such as 1,3-bis(5-(4-diphenylamino)phenyl-1,3,4-oxadiazol-2-yl)benzene, a polyacetylene derivative such as poly(1,2-bis-benzylthio-acetylene), and a phthalocyanine metal complex derivative such as phthalocyanine copper. Hole-injection materials, while still being able to transport holes, may have a hole mobility substantially less than the hole mobility of conventional hole-transport materials.

Light-emitting devices comprising the compounds described herein can be fabricated using techniques known in the art, as informed by the guidance provided herein. For example, a glass substrate can be coated with a high work functioning metal such as ITO which can act as an anode. After patterning the anode layer, a hole-injection and/or hole-transport layer may be deposited on the anode in that order. An emissive layer that includes an emissive component, can be deposited on the anode, the hole-transport, or the hole-injection layer. The emissive layer may contain a compound described herein, and/or a compound described herein may be part of an electron-transport layer and/or an electron-injecting layer, deposited in that order, or may be part of an electron-injecting and electron-transport layer. The cathode layer, comprising a low work functioning metal (e.g., Mg:Ag), can then be deposited, e.g., vapor evaporated. The device may also contain an exciton-blocking layer, an electron-blocking layer, a hole-blocking layer, a second emissive layer, or other layers that can be added to the device using techniques known in the art, as informed by the guidance provided herein.

In some embodiments, the OLED is configured by a wet process such as a process that comprises at least one of spraying, spin coating, drop casting, inkjet printing, screen printing, etc. Some embodiments provide a composition which is a liquid suitable for deposition onto a substrate. The liquid may be a single phase, or may comprise one or more additional solid or liquid phases dispersed in it. The liquid typically comprises a light-emitting compound, a host material described herein, and a solvent.

The present invention will be explained in detail with reference to specific examples which are not intended to limit the present invention. In the examples where conditions and/or structures are not specified, the skilled artisan in the art can readily provide such conditions and/or structures, in view of the present disclosure, as a matter of routine experimentation. The numerical numbers applied in specific examples may be modified by a range of at least ±50%, wherein the endpoints of the ranges may be included or excluded.

### Synthesis Example 1

### First Example of Synthesis of Formula 21

The compound of Formula 21 was synthesized as follows:

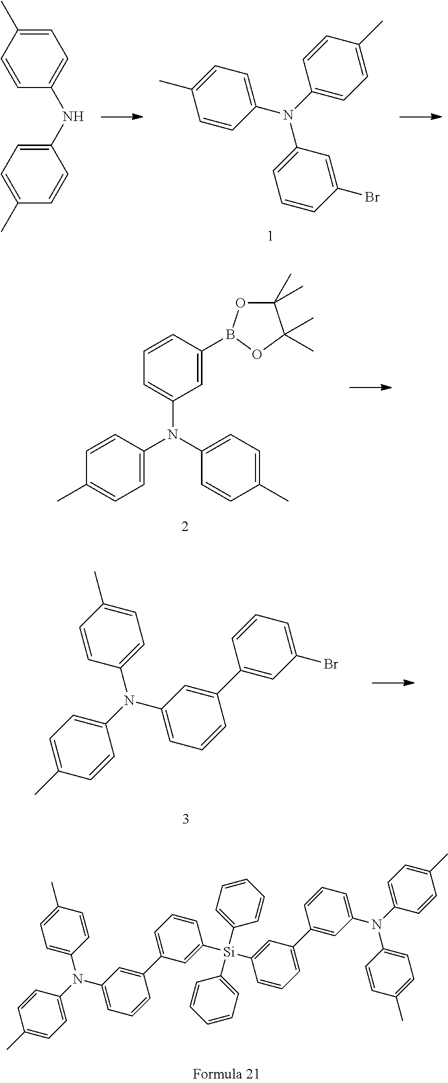

### Synthesis of Compound 1

A 250 ml two-neck round bottom flask and magnetic stir bar were oven-dried. Di-p-tolylamine (5.00 g, 25.3 mmol) was added followed by 3-iodobromobenzene (14.3 g, 50.7 mmol), [1,1′-bis(diphenylphosphino)ferrocene]dichloropalladium(II) (600 mg), and sodium t-butoxide (6.80 g, 70.8 mmol). Anhydrous toluene (100 ml) was added via cannula. Argon was bubbled into the mixture for 40 minutes and the vessel was heated to 70° C. while being stirred in an oil bath for 48 hours.

### Purification of Compound 1

The reaction mixture was diluted with ethyl acetate and poured into a saturated sodium bicarbonate aqueous solution in a reparatory funnel. The organic solution was washed with water and brine before being dried over solid magnesium sulfate, filtered, and concentrated to dryness on a rotary evaporator. The crude product was further purified by dry loading to silica gel and performing silica gel column chromatography using a gradient of pure hexane to 5% ethyl acetate in hexane as the eluent. Fractions containing the product were combined and dried, and the purified solid was recrystallized from methanol and stored in a freezer overnight to yield 6.26 g (70.2%) of a white crystalline material having an NMR spectrum consistent with the proposed structure.

### Synthesis of Compound 2

A 250 ml two-neck round bottom flask and magnetic stir bar were oven-dried. Potassium acetate (3.00 g, 36.5 mmol) was added and dried by applying a vacuum and using a heat gun. Then, 1 (3.00 g, 8.52 mmol) was added followed by bis(pinacolato)diboron (5.40 g, 21.2 mmol) and [1,1′-bis(diphenylphosphino)ferrocene]dichloropalladium(II) (311 mg). Anhydrous 1,4-dioxane (80 ml) was added and argon was bubbled into the solution for 1-hour. The reaction was heated to 80° C. while being stirred for overnight.

### Purification of Compound 2

The reaction mixture was poured into a saturated aqueous sodium bicarbonate solution and the organic materials were extracted with ethyl acetate using a separatory funnel. The organic solution was washed with brine before being dried over solid magnesium sulfate, filtered, and concentrated to dryness using a rotary evaporator. The crude material was applied as a dry load to a short silica column. Pure hexane was used to elute the excess diboron starting material, and then the eluent solvent was switched to pure dichloromethane to elute the product. All fractions which showed blue fluorescence under a UV lamp were pooled and concentrated to dryness using a rotary evaporator. The purified product was recrystallized from methanol and stored in a freezer for one night to yield 2.60 g (76.5%) of an off-white solid having an NMR spectrum consistent with the expected structure.

### Synthesis of Compound 3

A 250 ml two-neck round-bottom flask and magnetic stir bar were oven dried. 3-iodobromobenzene (4.00 g, 14.1 mmol), Compound 2 (2.50 g, 6.26 mmol), potassium carbonate (2.60 g, 18.8 mmol), tetrakis(triphenylphosphino)palladium(0) (375 mg), anhydrous 1,4-dioxane (50 ml) and water (8 ml) were added. Argon was bubbled through the solution for 50 minutes. The reaction vessel was heated to 75° C. in an oil bath while being stirred for 2 hours, then the temperature was increased to 90° C. overnight.

### Purification of Compound 3

The reaction mixture was poured into a separatory funnel containing a saturated aqueous solution of sodium bicarbonate. The organic products were extracted with ethyl acetate and washed with brine before drying over magnesium sulfate, filtration and concentration to dryness on a rotary evaporator. The crude material was dry loaded to silica then purified by silica column chromatography using 10% ethyl acetate in hexane as the mobile phase. The product-containing fractions were dried on a rotary evaporator then the product was recrystallized from hexane to yield 1.56 g (58.2%) of a snow-white solid having a proton NMR spectrum consistent with the expected structure.

### Synthesis of Compound of Formula 21

A 100 ml two neck round bottom flask and magnetic stir bar were oven dried then purged with nitrogen gas. Compound 3 (1.51 g, 3.53 mmol) was added and dissolved in anhydrous tetrahydrofuran (19 ml). Argon was bubbled into the system, then the vessel was cooled to −78° C. in a dry ice/acetone bath. After 15 minutes of stirring the solution in the −78° C. bath, a 1.6M solution of n-butylithium in hexane (2.30 ml, 3.69 mmol) was added drop wise. While this flask was kept cold and stirred for 2.5 hours, some diphenyldichlorosilane was vacuum distilled, and 0.35 ml (1.67 mmol) of this freshly distilled liquid was drawn into a syringe then added to the cold reaction vessel drop wise. After addition of the silane, the stirring rate was increased and the flask was allowed to naturally reach room temperature as the dry ice completely evaporated overnight.

### Purification of Compound of Formula 21

The room-temperature reaction solution was poured into a reparatory funnel containing a saturated aqueous solution of sodium bicarbonate. Ethyl acetate was added to extract the organic products. The ethyl acetate solution was then washed with water and brine before being dried over magnesium sulfate, filtered, and concentrated to dryness on a rotary evaporator. The crude extract was applied to a silica dry load and further purified by silica gel column chromatography using pure dichloromethane as the eluent. All fractions containing the product material were pooled, stripped of solvent, then recrystallized from hexane and stored in a freezer for one day. The crystals obtained after this process were further purified with another recrystallization from dichloromethane/methanol to yield 460 mg (31%) of the compound of Formula 21. Then, the filtrates from each recrystallization were combined and stripped of solvent, then applied as a silica gel dry load to a silica gel column chromatography using pure hexane to elute impurities, followed by 10% ethyl acetate in hexane to elute the product. Fractions containing the target material were pooled, dried, and fractionally recrystallized from hexane to yield an additional 530 mg of the compound of Formula 21, bringing the total yield after vacuum oven drying to 935 mg of the compound of Formula 21, or 63%. A proton NMR spectrum confirmed the product of the compound of Formula 21 (FIG. 6). The material was sublimed prior to use in organic electronic devices.

### Synthesis Example 2

### Second Example of Synthesis of Formula 21

Synthesis of the compound of Formula 21 using an alternative synthesis route is shown below:

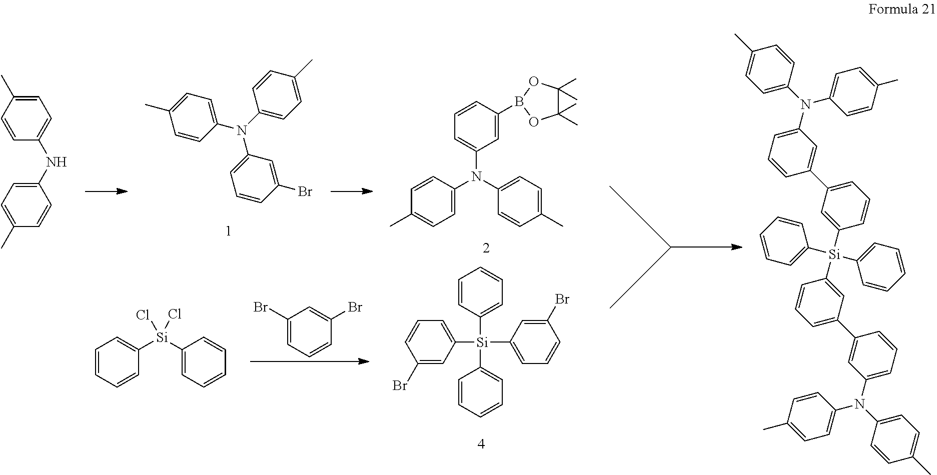

### Synthesis and Purification of Compound 1

Compound 1 was synthesized and purified in the same manner as in Example 1.

### Synthesis and Purification of Compound 2

Compound 2 was synthesized and purified in the same manner as in Example 1.

### Synthesis of Compound 4

A 100 ml two neck flask and magnetic stir bar was oven dried, then cooled under flowing argon gas. 1,3-dibromobenzene (2.6 g, 11 mmol) was added and then dissolved in anhydrous tetrahydrofuran (20 ml). The vessel was purged with argon gas and placed in a dry ice/acetone bath to maintain a temperature of −78° C. A solution of 1.6M n-butylithium in hexane (5.1 ml, 8.0 mmol) was added drop wise slowly. This mixture was stirred for 2 hours at −78° C. Then, freshly vacuum distilled diphenyldichlorosilane (0.80 ml, 3.9 mmol) was added drop wise with constant stirring. The reaction mixture was allowed to stir for overnight while the dry ice evaporated and the bath naturally reached room temperature.

### Purification of Compound 4

The reaction solution was poured into a separatory funnel containing filtered water. Ethyl acetate was added in three 115 ml portions to extract the organic materials. The combined ethyl acetate solution was washed with water and brine before being dried over solid magnesium sulfate, filtered, and concentrated to dryness on a rotary evaporator. The crude extract was applied as a silica dry load to a silica gel column chromatography using pure hexane as the eluent. Fractions containing the desired product were pooled then concentrated on a rotary evaporator. The purified solid was then subjected to a recrystallization in a mixture of dichloromethane and methanol and storage in a freezer for overnight. After filtration and vacuum drying, 1.2 g (63%) of a white solid was collected having a proton NMR spectrum perfectly consistent with the expected structure 4.

### Synthesis of Compound of Formula 21 by Suzuki Coupling Between Compound 4 and Compound 2

A 100 ml two neck round bottom flask and magnetic stir bar was oven dried. Compound 4 (1.0 g, 2.0 mmol) was added followed by Compound 2 (1.8 g, 4.5 mmol), potassium carbonate (0.86 g, 6.2 mmol), and tetrakis(triphenylphosphino)palladium(0) (0.12 g). Anhydrous 1,4-dioxane (35 ml) was added followed by pure water (5.0 ml). Argon was sparged into the liquid for 1 hour then the mixture was refluxed for 24 hours.

### Purification of Compound of Formula 21

The reaction mixture was poured into a separatory funnel containing water and the organic products were extracted with ethyl acetate. The ethyl acetate solution was washed with brine before being dried over solid magnesium sulfate, filtered and concentrated to dryness on a rotary evaporator. The crude extract was applied as a dry load to a silica gel column and chromatography was performed using a gradient of warm pure hexane to warm 1% ethyl acetate in hexane as the eluent. Fractions containing the product were pooled and dried, and the resulting solid was recrystallized from pure hexane and stored overnight in a freezer. After filtration and drying in a vacuum oven, 880 mg (50%) of a white solid was collected having the same exact mass of the target structure and 98.5% purity as measured by LC-MS. This material was sublimed before being included in organic electronic devices.

### Synthesis Example 3

### Synthesis of Formula 22

The compound of Formula 22 was synthesized as follows:

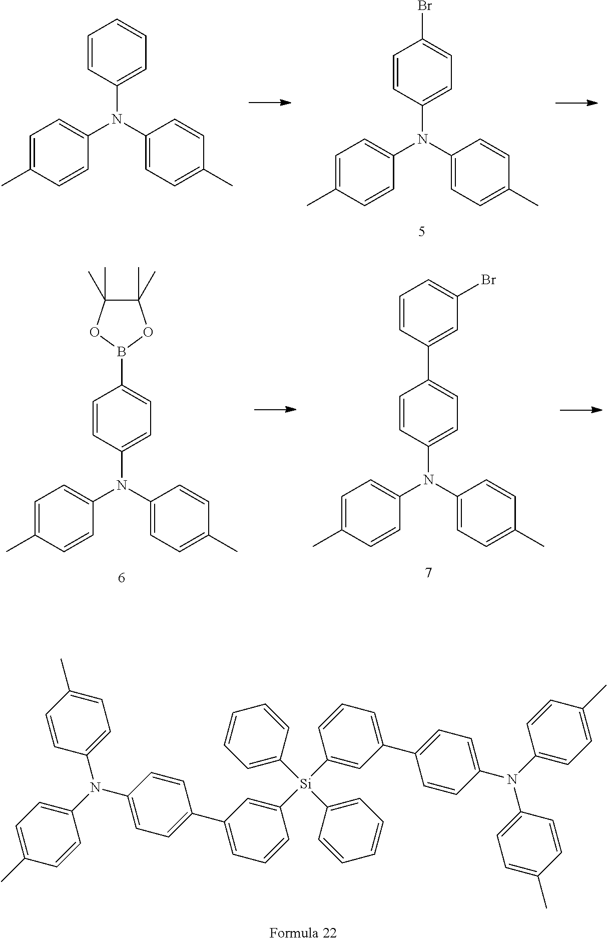

### Synthesis of Compound 5

A 500 ml two neck round bottom flask and magnetic stir bar was oven dried. After flushing with nitrogen gas, 4,4′-dimethyltriphenylamine (25.3 g, 92.5 mmol) was added. Anhydrous dichloromethane (250 ml) was added via cannula. The solution was cooled to 0° C. in an ice bath with stirring and covered with aluminum foil to exclude light, and N-bromosuccinimide (17.34 g, 97.4 mmol) was added in three portions over the course of 15 minutes. The reaction was allowed to reach room temperature naturally overnight with constant stirring.

### Purification of Compound 5

The reaction mixture was diluted with dichloromethane and then poured through a plug of silica gel, and rinsed with excess dichloromethane. The filtrate was concentrated to dryness on a rotary evaporator and then recrystallized from a large volume of methanol. The resulting white crystals were collected by filtration to yield 31.4 g (96%) of Compound 5 having a proton NMR spectrum consistent with the expected structure and free of any trace of impurities.

### Synthesis of Compound 6

A 100 ml two neck round bottom flask and magnetic stir bar was oven dried and then cooled under flowing argon gas. Compound 5 (2.5 g, 7.1 mmol) was added followed by bis(pinacolato)diboron (3.6 g, 14 mmol), potassium acetate (2.0 g, 24 mmol), and [1,1′-bis(diphenylphosphino)ferrocene]dichloropalladium(II) (0.26 g). Anhydrous 1,4-dioxane (60 ml) was added and then argon was sparged into the solution for 1 hour. The vessel was heated to 80° C. in an oil bath for 72 hours.

### Purification of Compound 6

The room temperature reaction solution was concentrated to dryness on a rotary evaporator, and the resulting solids were dissolved in dichloromethane and transferred to a separatory funnel. The organic solution was washed with aqueous sodium bicarbonate, water, and brine before being dried over solid magnesium sulfate, filtered, and stripped of solvent on the rotary evaporator. The crude extract was dissolved in minimal dichloromethane, then pipetted into a short silica plug and the product was eluted with 20% acetone in hexane. The filtrate was concentrated then dissolved in boiling methanol. A hot filtration was performed to remove some black insoluble material. The methanol was then removed by rotary evaporation and the semi-pure solid was further purified by dry loading to silica gel and performing silica gel column chromatography using 10% acetone in hexane as the eluent. Fractions containing the product were combined, dried, and recrystallized from methanol followed by storing in a freezer overnight. Upon filtration, washing with water, then drying in a vacuum oven, 2.24 g (79%) of a white solid having the proper proton NMR spectrum corresponding to Compound 6 was collected.

### Synthesis of Compound 7

3-iodobromobenzene (1.76 g, 6.22 mmol) was added to a clean 100 ml two neck flask containing a magnetic stir bar. Sodium carbonate (0.950 g, 8.96 mmol) was added followed by tetrakis(triphenylphosphino)palladium(0). Compound 6 (1.20 g, 3.01 mmol) was dissolved in anhydrous 1,4-dioxane (20 ml) and added to the reaction flask via syringe. Purified water (5.0 ml) was added and argon gas was sparged into the solution for 40 minutes. The flask was heated to 65° C. in an oil bath with constant stirring for 72 hours.

### Purification of Compound 7

The reaction solution was poured into a separatory funnel containing a saturated aqueous solution of sodium bicarbonate. Ethyl acetate was added to extract the organic products. The ethyl acetate solution was washed with water and brine before being dried over solid magnesium sulfate, filtered and concentrated to dryness on a rotary evaporator. The crude extract was then subjected to silica gel column chromatography using a dry load and 5% dichloromethane in hexane as the eluent. Product-containing fractions were pooled and dried, then the product was recrystallized from methanol and stored in a freezer overnight to yield 900 mg (70.3%) of a white solid having a proton NMR spectrum consistent with the predicted structure of Compound 7.

### Synthesis of Compound of Formula 22

Compound 7 (881 mg, 2.05 mmol) was added to a clean 50 ml round bottom flask containing a magnetic stir bar Anhydrous tetrahydrofuran (9 ml) was added to dissolve the solid. The flask was submerged into a dry ice/acetone bath to maintain a temperature of −78° C. A 1.6M solution of n-butylithium (1.4 ml, 2.2 mmol) was added drop-wise to the stirring solution and stirring was continued for 40 minutes. Then, diphenyldichlorosilane (0.21 ml, 1.0 mmol) was added drop-wise and the mixture was allowed to naturally reach room temperature overnight.

### Purification of Compound of Formula 22

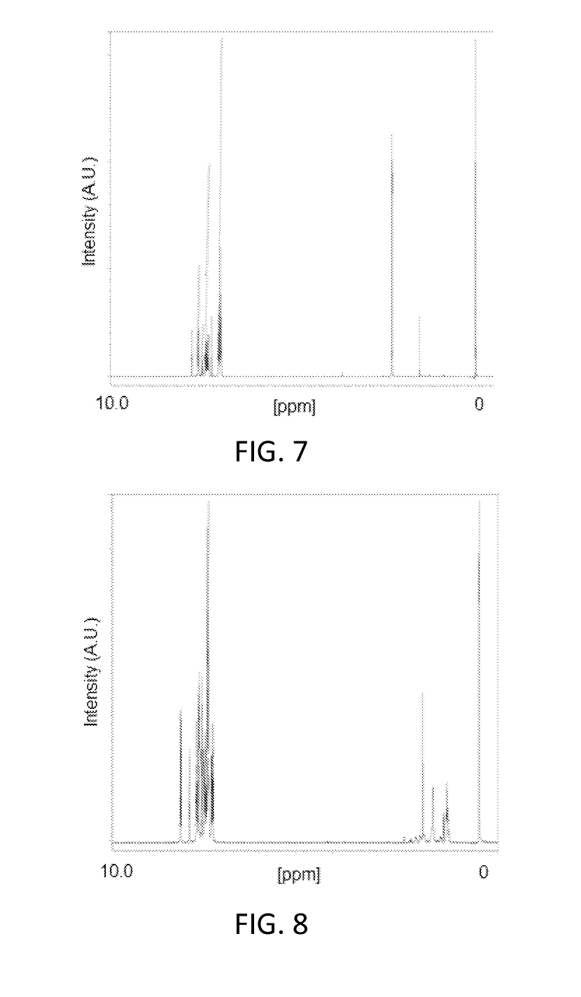

The reaction mixture was diluted with dichloromethane then passed through a short silica plug which was equilibrated in dichloromethane. Dichloromethane, acetone, then a mixture of dichloromethane and acetone was poured through the plug to elute all of the organic materials. The filtrate was concentrated on a rotary evaporator then recrystallized from a mixture of dichloromethane and methanol and stored in a freezer overnight to yield 600 mg (66%) of a white solid having a proton NMR spectrum consistent with the product (FIG. 7). This material was further purified by sublimation before being used in an organic electronic device.

### Synthesis Example 4

### Synthesis of Formula 23

The compound of Formula 23 was synthesized as follows:

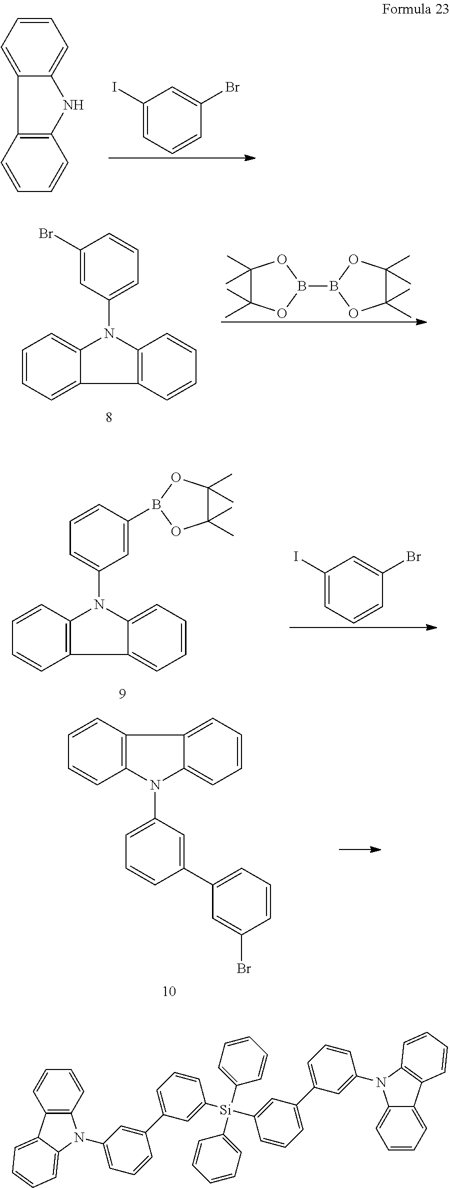

### Synthesis of Compound 8

A 500 ml two neck round bottom flask containing a magnetic stir bar was oven dried. 3-Iodobromobenzene (17 g, 60 mmol) was added followed by carbazole (5.0 g, 30 mmol), sodium tert-butoxide (8.0 g, 83 mmol), and acetato(2′-di-tert-butylphosphino-1,1′-biphenyl-2-yl)palladium(II) (200 mg). Anhydrous toluene (100 ml) was added and argon was sparged into the liquid for one hour. The flask was then heated to 95° C. in an oil bath for 72 hours.

### Purification of Compound 8

The reaction mixture was poured into a separatory funnel containing a saturated aqueous solution of sodium bicarbonate. Ethyl acetate was added to help extract the organic materials. The ethyl acetate and toluene solution was washed with water and brine before being dried over solid magnesium sulfate, filtered and concentrated to dryness on a rotary evaporator. The crude material was applied as a dry load to a silica gel column and chromatography was performed using pure hexane as the eluent. The product-containing fractions were pooled and dried to yield 2.7 g (28%) of a glassy material having a proton NMR spectrum consistent with the expected structure of Compound 8. It was used without further purification in the next step.

### Synthesis of Compound 9

A 500 ml round bottom flask and magnetic stir bar were oven dried, and potassium acetate (3.0 g, 31 mmol) was added and dried by applying a vacuum and heating to 110° C. in an oil bath. Bis(pinacolato)diboron (5.3 g, 21 mmol) was added followed by [1,1′-bis(diphenylphosphino)ferrocene]dichloropalladium(II) (307 mg). Compound 8 (2.7 g, 8.4 mmol) was dissolved in anhydrous dioxane (80 ml) and added via syringe. Argon was sparged into the liquid for 30 minutes then the flask was submerged into an 80° C. oil bath with constant stirring for one week.

### Purification of Compound 9

The reaction mixture was concentrated to dryness on a rotary evaporator. Excess ethyl acetate was then added and the resulting solution was poured into a separatory funnel containing a saturated solution of aqueous sodium bicarbonate. The organic solution was washed with water and brine before being dried over solid magnesium sulfate, filtered, and concentrated to dryness on a rotary evaporator. The crude material was purified by dissolving in a minimal amount of dichloromethane and filtering this solution through a short silica plug eluting the product with a 1:1 solution of ethyl acetate and hexane. The filtrate was concentrated to dryness on a rotary evaporator and the resulting yellow oil was then dissolved in a minimal amount of room temperature methanol, and placed in a freezer overnight. The white material which crystallized from the solution was then filtered and dried to yield 2.7 g (87%) of Compound 9, whose structure was confirmed by proton NMR.

### Synthesis of Compound 10

A 200 ml round bottom flask and magnetic stir bar was oven dried. Compound 9 (2.7 g, 7.3 mmol) was added, followed by 3-iodobromobenzene (3.1 g, 11 mmol), potassium carbonate (3.0 g, 22 mmol), and tetrakis(triphenylphosphino)palladium(0). Anhydrous 1,4-dioxane (60 ml) and purified water (8.5 ml) was added, and argon was sparged into the solution for one hour. The reaction vessel was then placed in a 97° C. oil bath with constant stirring for 24 hours.

### Purification of Compound 10

The reaction mixture was concentrated to dryness on a rotary evaporator. Ethyl acetate and water were then added to dissolve all of the material in the flask, which was then poured into a separatory funnel containing a saturated aqueous solution of sodium bicarbonate. The organic layer was washed with water and brine, dried over solid magnesium sulfate, then filtered and concentrated to dryness on a rotary evaporator. The crude material was purified by applying to a short silica gel column as a dry load and the chromatography was performed using pure hexane as the eluent. Fractions containing the product were pooled and dried, and then the product was further purified by recrystallization from a mixture of dichloromethane and methanol and stored in a freezer overnight to yield 2.5 g (86%) of white crystals having a proton NMR spectrum consistent with the expected chemical structure.

### Synthesis of Compound of Formula 23

To a 100 ml two neck round bottom flask containing a magnetic stir bar which was oven dried was added Compound 10 (2.47 g, 6.20 mmol) and anhydrous tetrahydrofuran (24 ml). The mixture was stirred at room temperature for a minute and then was submerged into a dry ice/acetone bath. After 20 minutes of constant stirring in the cold bath, a 1.6M solution of n-butylithium in hexane (3.88 ml, 6.20 mmol) was added drop-wise. The solution was stirred for 2 hours while submerged in the dry ice/acetone bath. Then, diphenyldichlorosilane (0.627 ml, 2.97 mmol) which had been freshly vacuum distilled was added drop-wise, and the reaction mixture was allowed to naturally reach room temperature overnight with constant stirring. The reaction mixture was then briefly heated to reflux for 30 minutes before finally being allowed to cool back to room temperature.

### Purification of Compound of Formula 23

The reaction solution was poured into a reparatory funnel containing water. Ethyl acetate was added to extract the organic products. The organic layer was washed with brine before being dried over solid magnesium sulfate, filtered, and concentrated to dryness on a rotary evaporator. The crude material was purified by dry loading to a silica gel column and chromatography was performed using a gradient of 5% to 15% ethyl acetate in hexane as the mobile phase. Fractions containing the desired material were pooled and concentrated, resulting in 1.7 g (70%) of a white solid having a proton NMR spectrum in perfect agreement with the chemical structure of the compound of Formula 23 (FIG. 8). This material was further purified by sublimation before being incorporated in an organic electronic device.

### Synthesis Example 5

### Synthesis of Formula 24

The compound of Formula 24 was synthesized as follows:

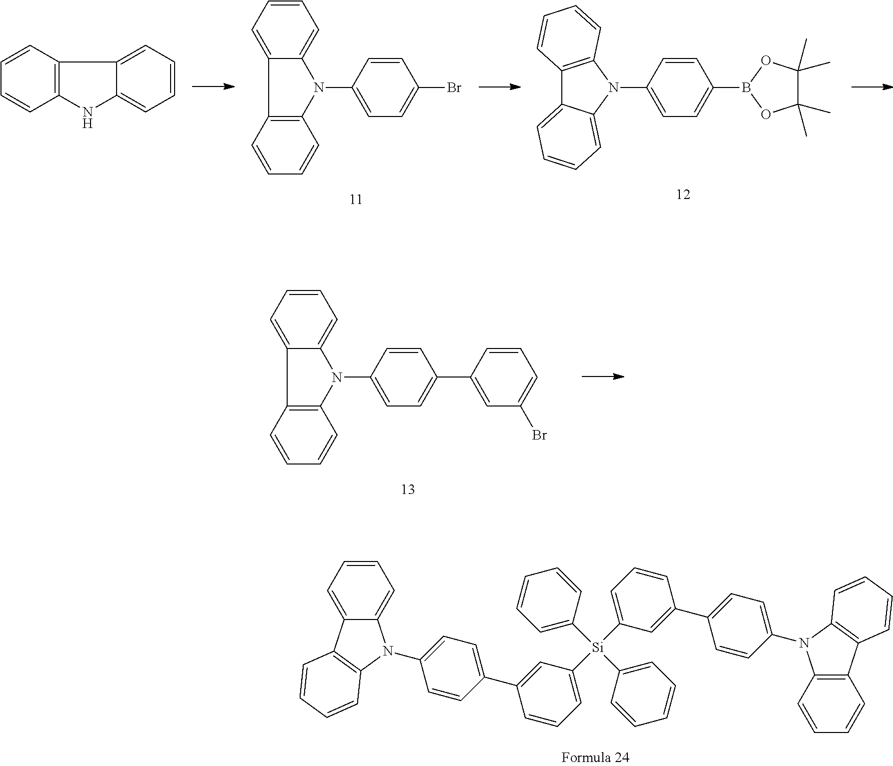

### Synthesis of Compound 11

A 250 ml two neck round bottom flask containing a magnetic stir bar was oven dried. 4-iodobromobenzene (5.00 g, 17.6 mmol) was added followed by carbazole (3.84 g, 23.0 mmol), copper powder (5.70 g, 89.7 mmol), potassium carbonate (12.2 g, 88.2 mmol) and a small amount of 18-crown-6 ether. Anhydrous N,N-dimethylformamide (90 ml) was added via syringe and argon was sparged into the liquid for 1 hour. With constant stirring, the reaction was heated to 150° C. in an oil bath for 5 hours, and then the temperature was reduced to 140° C. for one night.

### Purification of Compound 11

The reaction mixture was concentrated using a rotary evaporator. The residue was dissolved in ethyl acetate and filtered through a silica plug to remove excess copper powder and potassium carbonate. The filter was rinsed with dichloromethane and excess ethyl acetate to fully elute all of the organic products. The filtrate was concentrated and dried under a high vacuum to remove residual N,N-dimethylformamide. The crude product was further purified by dry loading to silica gel and performing silica gel column chromatography using pure hexane as the eluent. Fractions containing the target material were dried to yield 4.74 g (83.3%) of a white solid having a proton NMR spectrum consistent with Compound 11.

### Synthesis of Compound 12

A 250 ml two neck round bottom flask containing a magnetic stir bar was oven dried. Compound 11 (4.72 g, 14.6 mmol) was added followed by bis(pinacolato)diboron (8.80 g, 34.7 mmol), potassium acetate (4.31 g, 43.9 mmol), and [1,1′-bis(diphenylphosphino)ferrocene]dichloropalladium(II) (536 mg). Anhydrous 1,4-dioxane (˜100 ml) was added via cannula and argon was bubbled into the solution for 1 hour. The vessel was submerged in an 85° C. oil bath with constant stirring for 72 hours.

### Purification of Compound 12

The reaction solvent was removed using a rotary evaporator. The residue was dissolved in dichloromethane and poured into a reparatory funnel containing a saturated aqueous sodium bicarbonate solution. The organic layer was washed with water and brine before being dried over magnesium sulfate, filtered and concentrated. The crude extract was dissolved in minimal dichloromethane and poured through a silica plug, and the product was eluted through the plug with pure dichloromethane. The filtrate was concentrated on a rotary evaporator then recrystallized from methanol and stored in a freezer for one night. The crystallized solid was filtered to yield 4.38 g (80%) of a white material having a proton NMR spectrum consistent with the chemical structure of Compound 12.

### Synthesis of Compound 13

Compound 12 (4.30 g, 11.6 mmol), 3-iodobromobenzene (4.94 g, 17.5 mmol), potassium carbonate (4.82 g, 34.9 mmol), tetrakis(triphenylphosphino)palladium(0) (672 mg), anhydrous 1,4-dioxane (80 ml), and purified water (10 ml) were all added to a 250 ml two neck round bottom flask containing a stir bar which had been oven dried. Argon gas was bubbled into the liquid for one hour and the reaction was heated to 70° C. with constant stirring for 72 hours.

### Purification of Compound 13

The reaction was poured into a reparatory funnel containing a saturated aqueous solution of sodium bicarbonate. Ethyl acetate was added to extract the organic materials. The ethyl acetate layer was washed with water and brine before being dried over solid magnesium sulfate, filtered, and concentrated. The crude material was dry loaded to silica gel and silica gel column chromatography was performed using pure hexane as the eluent. The fractions containing the target material were pooled and dried to yield 2.76 g (59.5%) of a white solid having the proper proton NMR spectrum corresponding to Compound 13.

### Synthesis of Compound of Formula 24

A 100 ml two neck round bottom flask containing a magnetic stir bar was oven dried and argon purged. Compound 13 (2.70 g, 6.78 mmol) was added followed by anhydrous tetrahydrofuran (30 ml). The vessel was purged with argon gas while the flask was placed into a dry ice/acetone bath. While stirring the flask at −78° C., a solution of 1.6M n-butylithium in hexane (4.45 ml, 7.12 mmol) was added drop by drop via syringe. This solution was stirred for 2 hours at −78° C. while a batch of diphenyldichlorosilane was vacuum distilled. After the 2 hours, freshly distilled diphenyldichlorosilane (0.685 ml, 3.25 mmol) was added drop-wise via syringe. The reaction was allowed to naturally reach room temperature and was stirred for a weekend.

### Purification of Compound of Formula 24

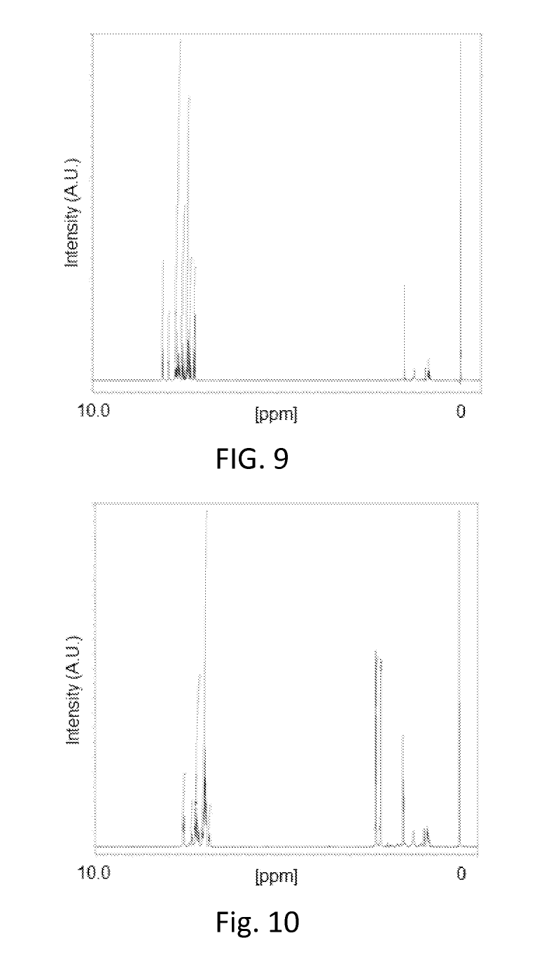

A saturated aqueous solution of sodium bicarbonate was added to the reaction flask to quench the reaction. The contents of the flask were then poured into a separatory funnel and ethyl acetate was added to extract the organic materials. The ethyl acetate layer was washed with water and brine before being dried over solid magnesium sulfate, filtered and concentrated on a rotary evaporator. The crude extract was further purified by dry loading to silica and performing silica gel column chromatography using a gradient of 10% dichloromethane in hexane to 30% dichloromethane in hexane as the mobile phase. Fractions containing the product were combined and dried under vacuum to yield 2.2 g (83%) of a white solid having a proton NMR spectrum consistent with the expected structure of the compound of Formula 24 (FIG. 9). This material was further purified by sublimation prior to use in organic electronic devices.

### Synthesis Example 6

### Synthesis of Formula 25

The compound of Formula 25 was synthesized as follows:

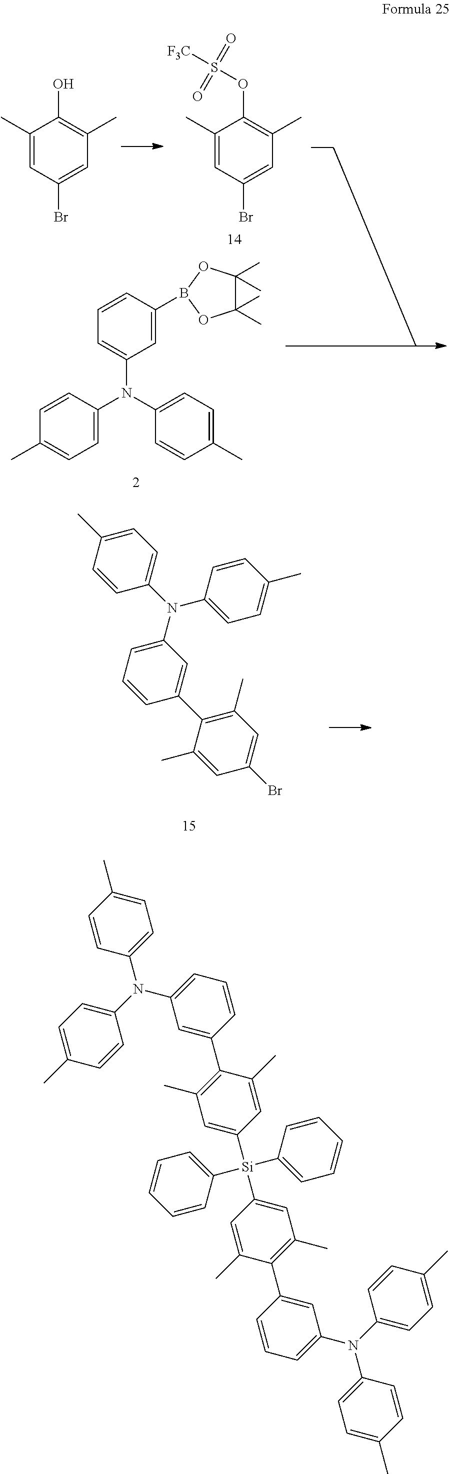

### Synthesis of Compound 14

A 100 ml two neck round bottom flask containing a magnetic stir bar and a 250 ml two neck round bottom flask containing a magnetic stir bar were oven dried. To the 100 ml flask was added anhydrous pyridine (20 ml) and the vessel was purged with argon. Trifluoromethanesulfonic anhydride (4.81 ml, 28.6 mmol) was added drop-wise to the 100 ml flask under the cover of an argon atmosphere and with constant stirring. A significant amount of gas and heat was generated during this process. While this solution was allowed to cool, anhydrous pyridine (30 ml) was added to the 250 ml flask. The 250 ml vessel was purged with argon and 4-bromo-2,5-dimethylphenol (5.00 g, 24.9 mmol) was added. The 250 ml flask containing pyridine and the phenol compound was cooled to −10° C. in a salted water ice bath with constant stirring. Once the solution contained in the 100 ml flask reached room temperature, it was taken up into a syringe and added drop-wise to the cold 250 ml flask containing the phenol. The resulting solution was stirred for 30 minutes at −10° C. and then room temperature for 1 hour.

### Purification of Compound 14

The reaction solution was diluted with dichloromethane and then poured into a separatory funnel where it was washed with saturated aqueous sodium bicarbonate, water (1600 ml), then dried over solid magnesium sulfate, filtered and concentrated on a rotary evaporator. The crude product was further purified by solution loading to a silica column from a dichloromethane solution. The chromatography was run using a solution of 10% ethyl acetate in hexane as the mobile phase. Fractions containing the product were pooled and dried yielding 7.65 g (92%) of a colorless liquid having a proton NMR spectrum consistent with Compound 14.

### Synthesis of Compound 15

A 100 ml two neck round bottom flask containing a magnetic stir bar was oven dried. Compound 14 (2.01 g, 6.03 mmol) was added followed by compound 2 (2.10 g, 5.26 mmol), tetrakis(triphenylphosphino)palladium(0) (318 mg), potassium carbonate (2.29 g, 16.6 mmol), anhydrous 1,4-dioxane (52 ml), and purified water (7.5 ml). Argon gas was sparged into the solution for 1 hour and the flask was subsequently submerged into an oil bath and heated to 60° C. with constant stirring for one night.

### Purification of Compound 15

The reaction mixture was concentrated on a rotary evaporator, then diluted with dichloromethane and water and was poured into a separatory funnel containing saturated aqueous sodium bicarbonate. The organic layer was washed with water and brine before being dried over solid magnesium sulfate, filtered and dried on a rotary evaporator. The crude material was dissolved in minimal ethyl acetate and filtered through a silica plug which was flushed with a 10% solution of ethyl acetate in hexane to elute the product. The filtrate was concentrated on a rotary evaporator, then dry loaded to silica and silica gel column chromatography was performed using 10% ethyl acetate in hexane as the mobile phase. All product-containing fractions were pooled and dried, then the material was further purified by recrystallizing from methanol and placing in a freezer for one night. Upon filtration, 1.32 g (55%) of a crystalline solid was collected having a proton NMR spectrum consistent with the expected structure of Compound 15.

### Synthesis of Compound of Formula 25

A 100 ml two neck round bottom flask containing a magnetic stir bar was oven dried and Compound 15 (1.31 g, 2.87 mmol) was added followed by anhydrous tetrahydrofuran (15 ml). The vessel was submerged in a dry ice/acetone bath with constant stirring. A solution of 1.6M n-butylithium in hexane (1.80 ml, 2.88 mmol) was added drop-wise to the stirring solution. The resulting mixture was stirred for 105 minutes after which freshly vacuum distilled diphenyldichlorosilane (0.285 ml, 1.35 mmol) was added drop-wise with constant stirring. The reaction flask was covered with aluminum foil and stirred for the weekend as it naturally reached room temperature.

### Purification of Compound of Formula 25

The reaction mixture was poured into a separatory funnel containing a saturated aqueous sodium bicarbonate solution. Ethyl acetate was added to extract the organic materials. The ethyl acetate solution was washed with brine before being dried over solid magnesium sulfate, filtered and concentrated on a rotary evaporator. The material was dry loaded to silica and silica gel column chromatography was performed using a gradient of 10% dichloromethane in hexane to 20% dichloromethane in hexane as the mobile phase. Fractions containing the product were pooled and dried resulting in 0.254 g (19%) of a white powder having an NMR spectrum consistent with the expected structure of the compound of Formula 25 (FIG. 10).

### Experimental Examples

Photoluminescence (PL) spectra were recorded on a FluoroMax-3 fluorescence spectrophotometer (Horiba Jobin Yvon, Edison, New Jersey, USA). 2-Methyltetrahydrofuran (2-MeTHF) (Aldrich, spectroscopic grade) was used as received. 2M (2 mg of sample/1 mL of 2-MeTHF) solution was prepared and then transferred to a quartz tube prior to measurement. Then, the sample was frozen by liquid nitrogen at 77K. The phosphorescent emission spectrum was recorded and the highest-energy vibronic band was determined to calculate triplet (Ti) energy level.

Cyclic voltammetry (CV) was carried out in nitrogen-purged anhydrous N,N-dimethylformamide (DMF) (Aldrich) at room temperature with Echo-Chemie potentiostat/galvanostat (Echo Chemie/Metrohm Autolabe B.V., Utrecht, the Netherlands) Tetra-n-butylammonium hexafluorophosphate (TBAPF6) and DMF were purchased from Aldrich and used as received. Supporting electrolyte solution (0.1M) with TBAPF6 and analyte, e.g., the compound of Formula 21, (0.1 mM) in DMF was used for CV study. Formal potentials were calculated as the average of cyclic voltammetric anodic and cathodic peaks and ferrocenium-ferrocene (Fc+/Fc) as the internal standard was introduced to calibrate HOMO (highest occupied molecular orbital) and LUMO (lowest unoccupied molecular orbital) energy at each experiment. Scan rate of 100 mV/s was used unless otherwise stated.

Triplet (T1) Energy Calculation:

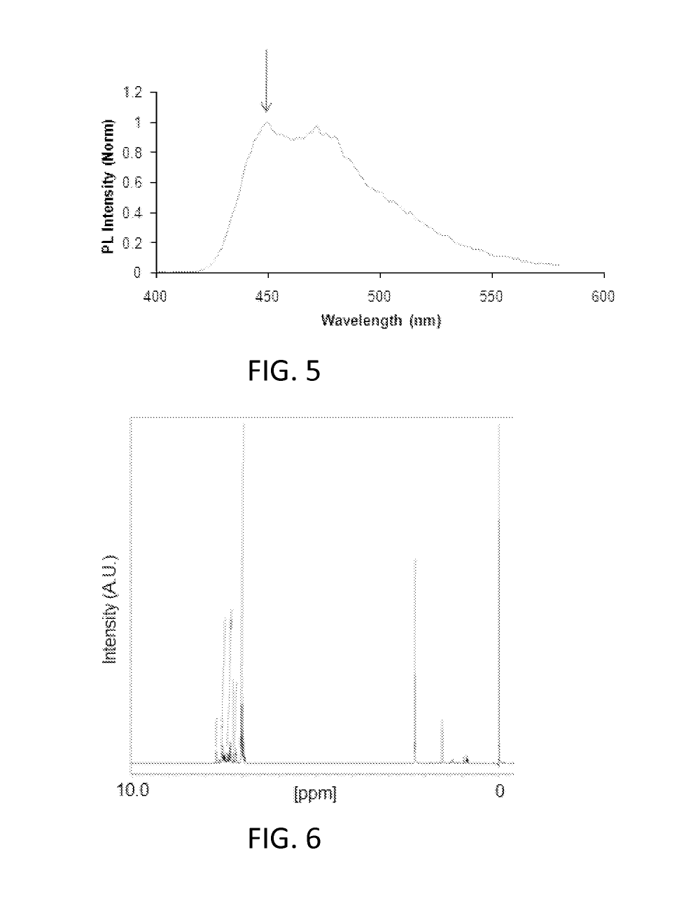

Triplet energy was recorded on a FloroMax-3 spectrometer (Jobin Yvon Horiba, Edison, N.J.) with phosphorescence spectra at 77 K. It was determined by the highest-energy vibronic sub-band of the phosphorescence spectra. For example, the following compound (Formula 21) showed 450 nm (indicated by red arrow) as the highest-energy band (see FIG. 5) and its wavelength was then converted to 2.76 eV as triplet energy.

HOMO/LUMO Energy Calculation:

HOMO energy was direcTly determined by oxidation potential with respect to redox of ferrocene/ferrocenium in anodic scan of the sample dissolved in DMF. For example, potential difference between the reference (ferrocene/ferrocenium) and the sample (Formula 21) was determined to be 0.48 eV. Therefore, using vacuum level of ferrocene as 4.8 eV, HOMO of the compound of Formula 21 was determined to be −5.28 eV. LUMO energy was determined by equation of band gap Eg(eV)=HOMO−LUMO. Since Eg (eV) (3.3 eV) of the compound of Formula 21 was estimated by onset value of UV-vis spectroscopy, so the LUMO of the compound of Formula 21 was calculated as −1.98 eV.

In the same manner as for the compound of Formula 21, T1, HOMO, and LUMO were determined as follows:

TABLE 1

| ID | Formula 21 |
|---|---|
| Structure | 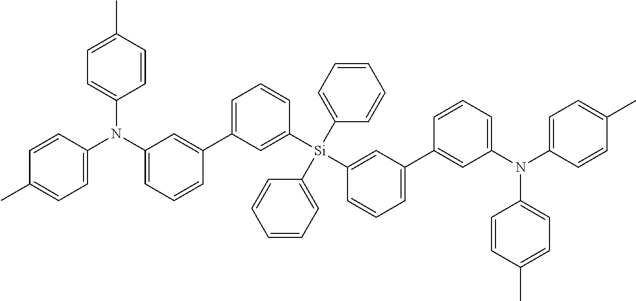 |
| T1 (max) | 2.76 |
| (eV) | |
| HOMO | −5.28 |
| (eV) | |
| LUMO | −1.92 |
| (eV) | |
| ID | Formula 22 |
| Structure | 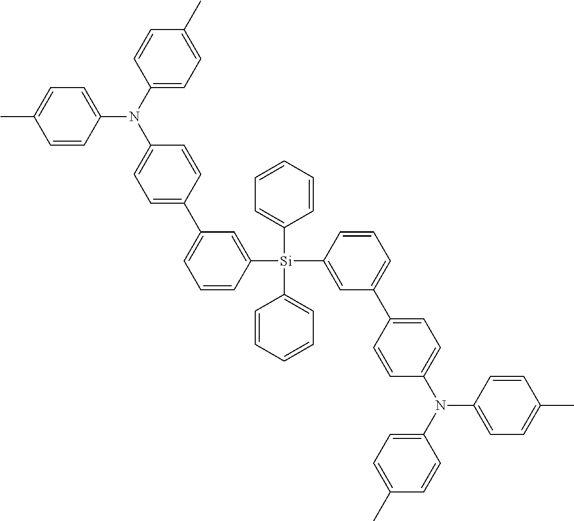 |
| T1 (max) | 2.56 |
| (eV) | |
| HOMO | −5.24 |
| (eV) | |
| LUMO | −1.89 |
| (eV) | |
| ID | Formula 23 |
| Structure | 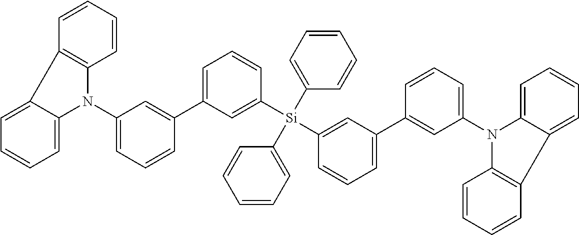 |
| T1 (max) | 2.86 |
| (eV) | |
| HOMO | −5.54 |
| (eV) | |
| LUMO | −2 |
| (eV) | |
| ID | Formula 24 |
| Structure | 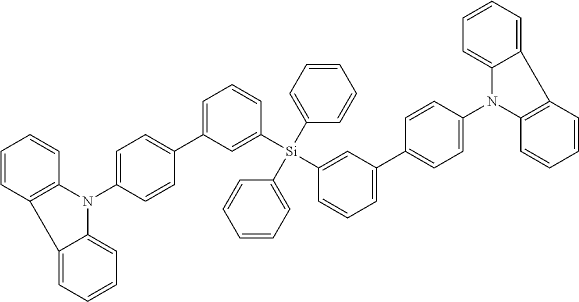 |
| T1 (max) | 2.74 |
| (eV) | |
| HOMO | −5.69 |
| (eV) | |
| LUMO | −2.08 |
| (eV) | |
| ID | Formula 25 |
| Structure | 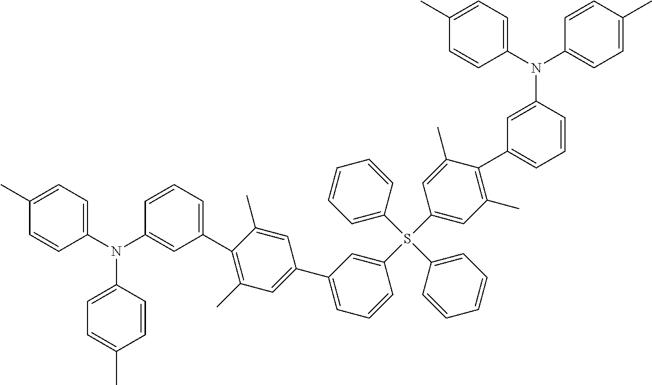 |
| T1 (max) | 2.76 |
| (eV) | |
| HOMO | −5.26 |
| (eV) | |
| LUMO | −1.91 |
| (eV) | |

Device Examples: OLED Device Configuration and Performance

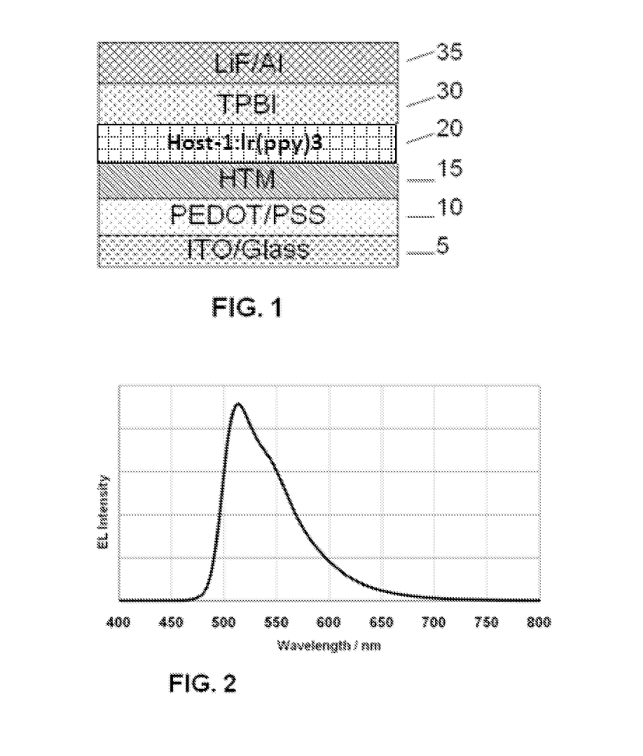

An example of a configuration of a device comprising a compound described herein is shown in FIG. 1. Such a device comprises the following layers in the order given: an ITO anode (ITO/Glass) 5, a PEDOT/PSS hole-injection layer (PEDOT/PSS) 10, a hole-transport layer (HTM) 15, a light-emissive layer (Host-1:lr(ppy)₃) 20, a TPBI electron-transport and hole-blocking layer (TPBI) 30, and a LiF/Al cathode (LiF/Al) 35.

For these particular examples, the ITO anode 5 was about 150 nm thick; the PEDOT hole injection layer 10 was about 30 nm thick; the hole-transport layer 15 was about 40 nm thick; the light-emissive layer 20 was about 30 nm thick; the TPBI electron transport and hole blocking layer 30 was about 30 nm thick; the LiF sublayer (not shown) of the cathode 35 was about 0.5 nm thick; and the Al sublayer of the cathode (not shown) was about 120 nm thick. The device was then encapsulated with a getter attached glass cap to cover the emissive area of the OLED device in order to protect it from moisture, oxidation or mechanical damage. Each individual device had an area of about 8 mm².

Fabrication of Light-Emitting Devices:

The ITO substrate having sheet resistance of about 14 ohm/sq was cleaned ultrasonically and sequentially in detergent, water, acetone and then IPA; and then dried in an oven at 80° C. for about 30 min in an ambient environment. Substrates were then baked at about 200° C. for about 1 hour in an ambient environment, then under UV-ozone treatment for about 30 minutes. PEDOT:PSS (hole-injection material) was then spin-coated on the annealed substrate at about 4000 rpm for about 30 sec. The coated layer was then baked at about 100° C. for 30 min in an ambient environment, followed by baking at 200° C. for 30 min inside a glove box (N₂ environment). Each substrate was then transferred into a vacuum chamber, where a hole-transporting material (TcTa, the compound of Formula 21, the compound of Formula 22, or DTASi) was vacuum-deposited at a rate of about 0.1 nm/s rate under a base pressure of about 2×10⁻⁷ torr. Then Ir(ppy)₃ (5 wt %) was co-deposited with a host material at about 0.005 nm/s and about 0.10 nm/s, respectively to form the first emissive layer. 1,3,5-Tris(1-phenyl-1H-benzimidazol-)2-yl)benzene (TPBI) was then deposited at a rate of about 0.1 nm/s on top of the emissive layer. A layer of lithium fluoride (LiF) (electron injection material) was deposited at a rate of about 0.005 nm/s followed by deposition of the cathode as Aluminum (Al) at about a rate of 0.3 nm/s, thereby producing a device. The first emissive layer may be any conventional or suitable emissive layer (such as those disclosed in a co-pending U.S. patent application Ser. No. 13/016,665, the disclosure of which is incorporated herein by reference in its entirety), and a second emissive layer can additionally be disposed thereon.

Device efficiencies of each device measured at 1000 nit are shown in Table 2:

TABLE 2

| Device | HTM | CE (cd/A) | PE (lm/w) |
|---|---|---|---|
| A | TcTa | 85.0 | 58.4 |
| B | Formula 21 | 91.0 | 75.0 |
| C | Formula 22 | 57.0 | 46.4 |
| D | DTASi | 75.1 | 60.3 |

TcTa: 4,4′,4″-Tri(9-carbazoyl)triphenylamine

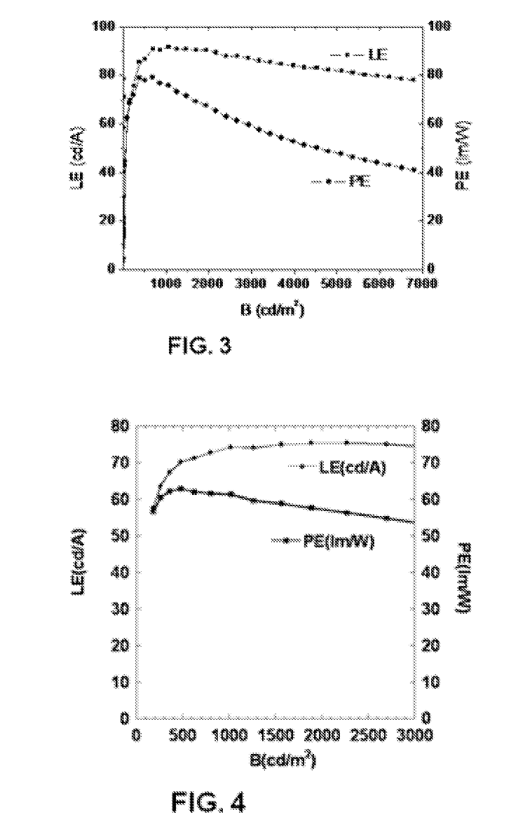

EL spectra were measured with a Spectrascan spectroradiometer PR-670 (Photo Research, Inc., Chatsworth, Calif., USA); and I-V-L characteristics were taken with a Keithley 2612 SourceMeter (Keithley Instruments, Inc., Cleveland, Ohio, USA) and PR-670. FIG. 2 shows the relationship between EL intensity and wavelength of Devices A to D. All of the devices show substantially the same EL spectra. FIG. 3 shows the relationship between LE (light efficiency), PE (power efficiency), and B (brightness) of Device B. FIG. 4 shows the relationship between LE (light efficiency), PE (power efficiency), and B (brightness) of Device D. As can be understood, Device B shows significantly high light efficiency and power efficiency, especially at relatively low brightness, as compared with Device D.

Although the claims have been explained in the context of certain preferred embodiments and examples, it will be understood by those skilled in the art that the present claims extends beyond the specifically disclosed embodiments to other alternative embodiments and/or uses and obvious modifications and equivalents thereof. Thus, it is intended that the scope of the present claims should not be limited by the particular disclosed embodiments described above.

What is claimed is:

1. A compound represented by a formula: 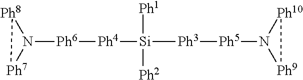
wherein each dashed line indicates an optional bond; and Ph¹, Ph², Ph³, Ph⁴, Ph⁵, Ph⁶, Ph⁷, Ph⁸, Ph⁹, and Ph¹⁰ are independently optionally substituted phenyl or phenylene.

2. The compound of claim 1 represented by a formula: 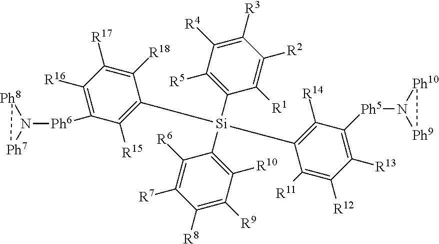
wherein R¹, R², R³, R⁴, R⁵, R⁶, R⁷, R⁸, R⁹, R¹⁰, R¹¹, R¹², R¹³, R¹⁴, R¹⁵, R¹⁶, R¹⁷, and R¹⁸ are independently R^{a} or —OR^{a}, wherein each R^{a} is independently H, C₁₋₆ hydrocarbyl, optionally substituted C₆₋₁₂ aryl, or an optionally substituted C₄₋₁₈ heterocycle.

3. The compound of claim 1 represented by a formula: 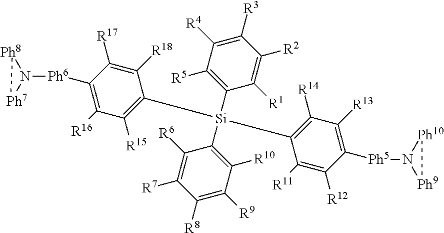
wherein R¹, R², R³, R⁴, R⁵, R⁶, R⁷, R⁸, R⁹, R¹⁰, R¹¹, R¹², R¹³, R¹⁴, R¹⁵, R¹⁶, R¹⁷, and R¹⁸ are independently R^{a} or —OR^{a}, wherein each R^{a} is independently H, C₁₋₆ hydrocarbyl, optionally substituted C₆₋₁₂ aryl, or an optionally substituted C₄₋₁₈ heterocycle.

4. The compound of claim 2, wherein at least one R^{a} is vinyl.

5. The compound of claim 3, wherein at least one R^{a} is vinyl.

6. The compound of claim 1, wherein Ph⁵ and Ph⁶ are independently m-phenylene or p-phenylene, and Ph⁵, Ph⁶, Ph⁷, Ph⁸, Ph⁹, and Ph¹⁰ are independently unsubstituted phenyl, or phenyl having 1, 2, 3, or 4 C₁₋₆ alkyl substituents.

7. The compound of claim 4, wherein Ph¹ and Ph² are unsubstituted phenyl; and, Ph³, Ph⁴, Ph⁵, Ph⁶, Ph⁷, Ph⁸, Ph⁹, and Ph¹⁰ are independently unsubstituted phenyl, or phenyl having 1, 2, 3, or 4 methyl substituents.

8. The compound of claim 5, wherein Ph¹ and Ph² are unsubstituted phenyl; and, Ph³, Ph⁴, Ph⁵, Ph⁶, Ph⁷, Ph⁸, Ph⁹, and Ph¹⁰ are independently unsubstituted phenyl, or phenyl having 1, 2, 3, or 4 methyl substituents.

9. The compound of claim 1, wherein 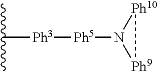
is selected from the group consisting of:

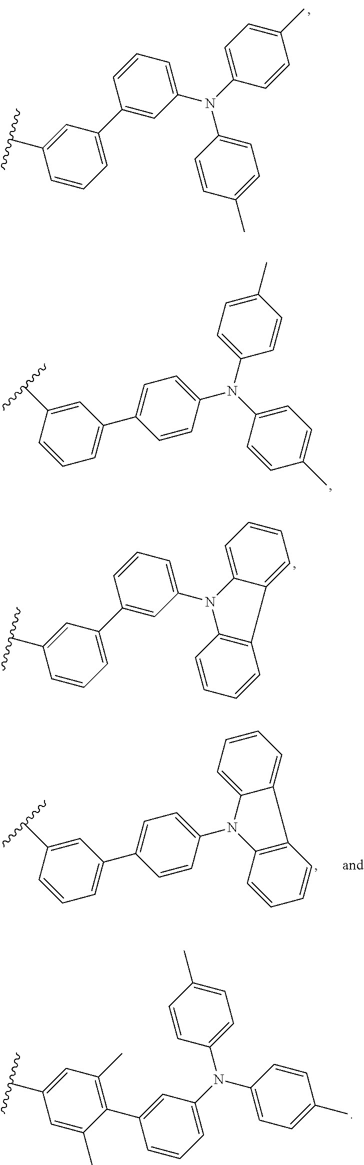

10. The compound of claim 7, wherein 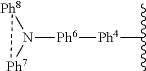
is selected from the group consisting of:

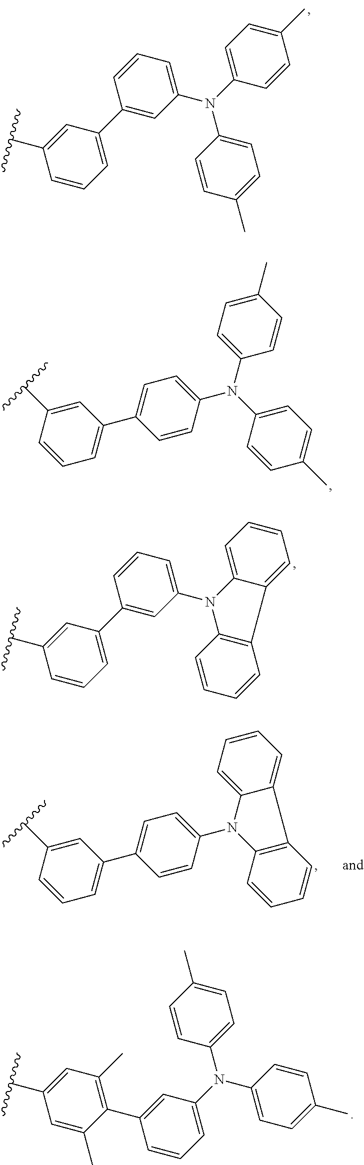

11. The compound of claim 8, wherein 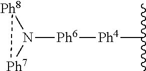
is selected from the group consisting of:

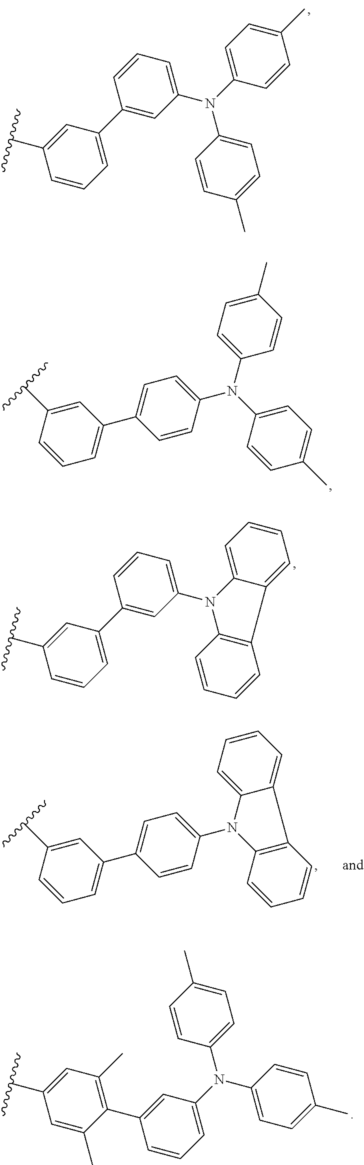

12. The compound of claim 1, which is selected from the group consisting of:

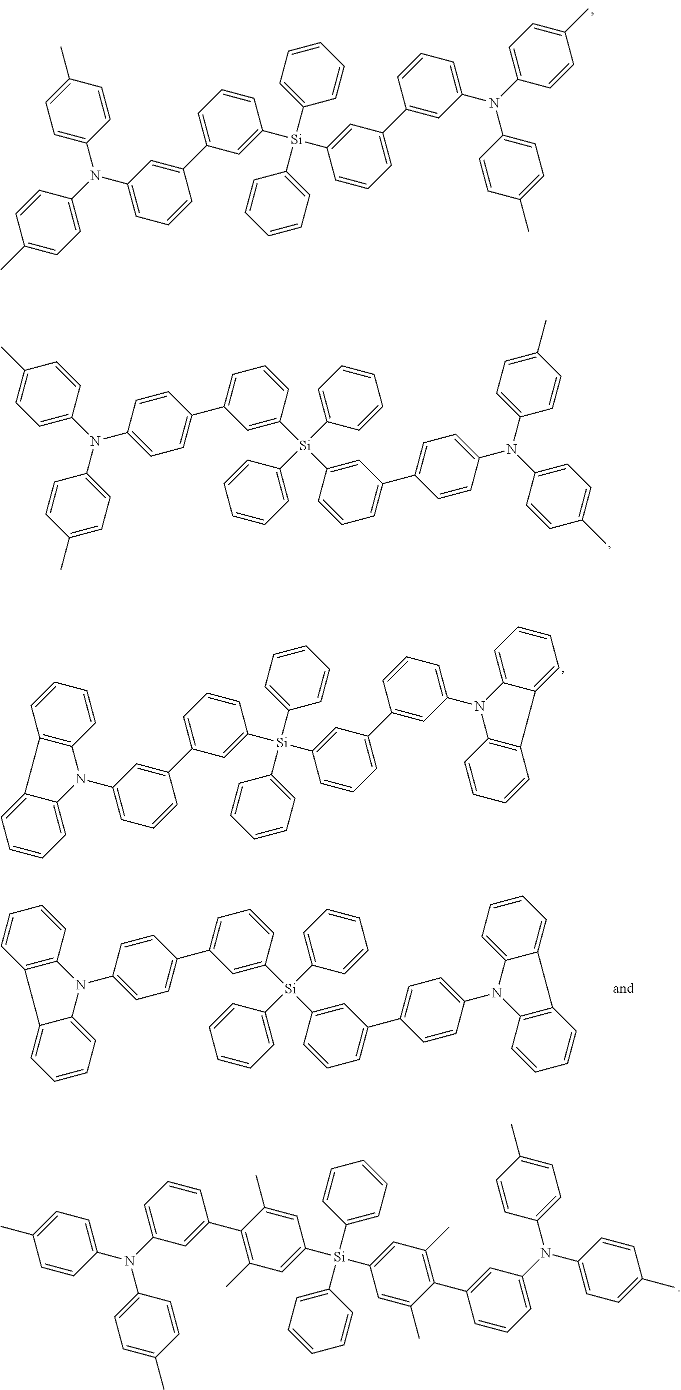

13. A light-emissive composition comprising a polymer and a compound according to claim 1 and a hole-transport compound.

14. A light-emitting device comprising a layer including a compound according to claim 1.

15. The device of claim 14, which comprises an organic light-emitting diode including the compound.

16. The device of claim 14, which comprises an emissive layer including the compound.

17. The device of claim 14, which comprises at least one layer selected from the group consisting of a hole-transport layer, hole-injecting layer, and hole-injecting and hole-transport layer, wherein the compound is in at least one layer.

18. The device of claim 14, wherein the layer is configured to transport holes in the presence of an electric field.

19. A method of transporting holes comprising:
disposing a hole-transport layer between a hole-donating layer and a hole-accepting layer, wherein the hole-transport layer comprises a compound according to claim 1; and
electrically charging the layers, thereby transporting holes.
